(19) United States
(12) Patent Application Publication
(10) Pub. No.: US 2018/0017604 A1
(43) Pub. Date: Jan. 18, 2018

(54) PARAMETER ESTIMATION AND CONTROL METHOD AND APPARATUS

(71) Applicant: THE UNIVERSITY OF SHEFFIELD, Sheffield Yorkshire (GB)

(72) Inventors: Edward John DAW, Sheffield Yorkshire (GB); Tega Boro EDO, Sheffield Yorkshire (GB)

(21) Appl. No.: 15/549,617

(22) PCT Filed: Feb. 12, 2016
(86) PCT No.: PCT/GB2016/050356

§ 371 Date: Aug. 8, 2017

(30) Foreign Application Priority Data
Feb. 13, 2015 (GB) 1502460.7

(51) Int. Cl. G01R 23/167; G01R 31/34; G06F 17/14

(52) U.S. Cl. CPC G01R 23/167; G01R 31/343; G06F 17/141

(57) ABSTRACT

A method for recursively estimating at least one parameter of a first oscillating component represented by one or more sampled noisy input signal waveforms, the method comprising, recursively generating from the one or more sampled noisy input signals an estimate of a Z-transform component corresponding to the first oscillating component, forming, from the estimated Z-transform component, one or more signals providing an indication of one or more of a frequency and an amplitude of the Z-transform component; and estimating, from the one or more signals, one or more of a frequency, a relative phase and an amplitude parameter of the first oscillating component.

Certain aspects of this invention relate to methods and apparatus for estimating parameters of oscillating components in noisy signals, and, more particularly, although not exclusively, the estimation of parameters of oscillating components in noisy signals for the control of electric motors. Certain aspects relate to control apparatus and methods, and processing apparatus and methods.

### BACKGROUND

Numerous applications require the measurement and estimation of the parameters or characteristics of oscillating signals or waveforms, such as frequency, phase, amplitude and so forth. For example, it is often necessary to measure the frequency and phase of an oscillating component, such as a sinusoid, in a noisy signal that may represent measurement data of a physical phenomenon such as the rotational frequency of an electric motor or a communications carrier signal. However, oscillating components may often be hidden or masked by noise or other signals and thus characterisation of these signals and estimating their parameters can be problematic. This task may also be further complicated if it is to be performed in real-time due to the complex nature of many wave parameterisation techniques.

Existing approaches to such characterisation may include the use of the discrete Fourier transform (DFT) for example, in order to transform a measured time-domain signal into the frequency domain such that oscillating components of a particular frequency may be identified. However, performing a Fourier transform is a computationally intensive operation and therefore does not present an efficient approach to the characterisation of oscillating components. Furthermore, since the frequency resolution of a discrete Fourier transform is dependent on the on the number of data elements and thus the size of the transform, in order to achieve a high frequency resolution, a large number of data elements are required, which in turn may place increased or unacceptable demands on available memory and data processing capabilities. Likewise, though a recursive DFT may be more efficient in terms of computational operations, the data storage requirements grow linearly with the length of the DFT, which may also lead to increased or unacceptable memory requirements. Further still, the DFT provides an estimate of the energy present in a band whose width is the reciprocal of the time duration of the DFT. Where this time interval is limited due to the capacity of the processor and memory to perform the DFT, it may be required to interpolate between DFT coefficients in order to estimate the parameters of an oscillating component. This interpolation adds further to the processing time and is also an additional source of error. Consequently, the provision of a low-complexity technique which provides reliable and accurate characterisation for oscillating components in noisy signals presents a technical problem to be solved.

### BRIEF SUMMARY OF THE DISCLOSURE

In accordance with an example of the present invention there is provided a method for recursively estimating at least one parameter of a first oscillating component of a sampled noisy input signal waveform, the method comprising: recursively generating from the sampled input signal an estimate of a Z-transform component corresponding to the first oscillating component; transforming the Z-transform component to yield one or more signals providing an indication of one or more of a frequency and an amplitude of the Z-transform component; and estimating, from the one or more signals, one or more of a frequency, a relative phase and an amplitude parameter of the first oscillating component.

This method presents a low-complexity and efficient approach to estimating one or more parameters of an oscillating component present in a sampled input signal. More particularly, transforming the output of a recursive z-transform to yield signals which provide an indication of the phase frequency and phase of the oscillating component and overcomes the need to perform complex analysis techniques such as a discrete Fourier transform for example.

In certain examples the one or more signals includes a first wave and a second wave, the first wave being substantially in-phase with the first oscillating component and the second wave being substantially out-of-phase with the first oscillating component.

In certain examples the Z-transform component has a substantially elliptical locus in the complex plane and the transforming of the Z-transform component comprises one or more of: aligning the major and minor axes of the elliptical locus with the real and imaginary axes; mapping the aligned elliptical locus to a substantially circular locus; and rotating the substantially circular locus so as to have an argument substantially equal to the phase of the first oscillating component.

Transforming the Z-transform component in such a manner provides an efficient approach to providing signals from which frequency, phase and amplitude of an oscillating signal since each step corresponds to a linear matrix multiplication.

In certain examples the square of the radius of the rotated substantially circular locus corresponds to an action variable of the first oscillating component and the argument of the rotated substantially circular locus corresponds to an angle variable of the first oscillating component, the action variable being given by the squared modulus of the transformed Z-transform component and the angle variable being given by the argument of the transformed Z-transform component.

In certain examples the first wave is formed from the real parts of the transformed Z-transform component, and the second wave is formed from the imaginary parts of the transformed Z-transform component.

In certain examples the first and second waves each have an amplitude substantially equal to the amplitude of the first oscillating component.

In certain examples the generation of the Z-transform component is based on a predetermined oscillation frequency and a predetermined bandwidth associated with the Z-transform.

In certain examples the bandwidth of the Z-transform is less than a frequency at which the input waveform is sampled.

In certain examples the predetermined oscillation frequency and the predetermined bandwidth vary with time.

In certain examples the action variable corresponds to an estimate of the squared amplitude of the first oscillating component, and the angle variable corresponds to the phase of the first oscillating component.

In certain examples the method further comprises tracking a frequency of the first oscillating component, the tracking comprising: estimating a frequency difference between the estimated frequency and the frequency of the first oscillating component; and updating the predetermined oscillation frequency based upon the estimated frequency difference.

In certain examples the method further comprises estimating a frequency shift of the first oscillating component, the estimating comprising: estimating a frequency difference between the estimated frequency and the frequency of the first oscillating component; updating the predetermined oscillation frequency based upon the estimated frequency difference; and calculating a difference between frequency estimates of the first oscillating component before and after the updating of the predetermined oscillation frequency.

Estimating a difference between the frequency of the oscillating component and the estimate of the frequency allows feedback to be provided to the estimation procedure to track a time varying signal, thus enabling a phase-locked loop to be formed. The local oscillator equivalent is based upon the one or more signals yielded by the parameter estimation technique and are thus related to the phase of the oscillation of interest. Since at least one of these signals is in phase with the oscillation of interest, only the frequency of the oscillation is required to be tuned in order to lock the phase-locked loop. Therefore the time taken to achieve a lock is reduced compared to conventional phase-locked loops in which both the phase and frequency of the local oscillator are required to be tuned.

In certain examples estimating the frequency difference is performed using homodyne detection.

In certain examples the sampled input signal waveform includes a second oscillating component, and the method includes: subtracting the first wave from the sampled input signal to generate a modified sampled input signal from which the first oscillating component has been substantially removed.

The subtraction of the first oscillating component enables a dominant signal in an input signal waveform to be cancelled and the parameters of an underlying signal to be more accurately characterised.

In certain examples the method comprises estimating one or more of a frequency, a relative phase and an amplitude parameter of the second oscillating component subsequent to subtracting the first wave from the sampled input signal, using a method comprising: recursively generating from the modified sampled input signal an estimate of a Z-transform component corresponding to the second oscillating component; transforming the Z-transform component corresponding to the second oscillating component to yield one or more further signals (e.g. further D and Q Waves) providing an indication of one or more of a frequency and an amplitude of the Z-transform component corresponding to the second oscillating component; and estimating, from the one or more further signals, one or more of a frequency, a relative phase and an amplitude parameter of the second oscillating component.

In certain examples the input signal waveform corresponds to a current flowing in a drive coil (or winding) of an electric motor, and the first oscillating component corresponds to a drive current of the electric motor.

The application of the parameter estimation technique to electric motors control enables motor control to be performed through the application of a single back-EMF sensor to the drive coils of an electric motor, rather than via the use of a plurality of sensors as in existing techniques. A motor control technique with reduced complexity is thus provided, in which the likelihood of failure due to sensor malfunction is also reduced.

In certain examples the second oscillating component corresponds to a current induced by a back electromotive force associated with a rotation of a rotor of the electric motor relative to the stator of the electric motor, and a phase of the second oscillating component corresponds to a position of the rotor of the electric motor relative to a stator of the electric motor.

In certain examples the method comprises controlling, based on at least one of the estimated frequency, phase and amplitude of the second oscillating component, a drive voltage applied to the drive coil.

In certain examples the drive voltage comprises a sinusoid and controlling the drive voltage comprises controlling one or more of the phase and amplitude of the sinusoid.

In certain examples the controlling of the drive voltage comprises: estimating a phase difference between the second oscillating component and the estimated phase of the second oscillating component; decreasing the drive voltage amplitude when the phase of the second oscillating component leads the estimated phase of the second oscillating component; and increasing the amplitude of the drive voltage if the phase of second oscillating component lags the estimated phase of the second oscillating component.

In certain examples the drive voltage comprises a sinusoid and controlling the drive voltage comprises generating the sinusoid based on one or more of the first and second waves associated with the second oscillating component.

In certain examples the method comprises controlling the frequency of the sinusoid by adjusting the predetermined oscillation frequency.

In certain examples the method comprises forming the sampled input signal waveform from a feedback signal derived from at least one of the one or more signals, whereby the one or more signals oscillate with a frequency corresponding to the predetermined oscillation frequency.

In certain examples the method comprises forming the sampled input signal waveform from the first wave.

Another example of the invention provides parameter estimation apparatus configured to recursively estimating at least one parameter of a first oscillating component of a sampled noisy input signal waveform, the apparatus comprising: a Z-transform unit configured to generate from the sampled input signal an estimate of a Z-transform component corresponding to the first oscillating component; a transform unit configured to transform the Z-transform component to yield one or more signals providing an indication of one or more of a frequency and an amplitude of the Z-transform component; and an estimating unit configured to estimate, from the one or more signals, one or more of a frequency, a relative phase and an amplitude parameter of the first oscillating component.

In certain examples the one or more signals includes a first wave and a second wave, the first wave being substantially in-phase with the first oscillating component and the second wave being substantially out-of-phase with the first oscillating component.

In certain examples the Z-transform component has a substantially elliptical locus in the complex plane and the transforming of the Z-transform component by the transform unit comprises one or more of: aligning the major and minor axes of the elliptical locus with the real and imaginary axes; mapping the aligned elliptical locus to a substantially circular locus; and rotating the substantially circular locus so as to have an argument substantially equal to the phase of the first oscillating component.

In certain examples the square of the radius of the rotated substantially circular locus corresponds to an action variable of the first oscillating component and the argument of the rotated substantially circular locus corresponds to an angle variable of the first oscillating component, the action variable being given by the square of the modulus of the transformed Z-transform component and the angle variable being given by the argument of the transformed Z-transform component.

Another example provides parameter estimation apparatus configured to implement a method in accordance with the first aspect.

Another example provides motor control apparatus adapted to implement a method in accordance with the first aspect, wherein said waveform is a waveform associated with operation of a motor, the control apparatus being further adapted to generate a drive voltage, for application to a winding of the motor, in accordance with (i.e. from, or using) said one or more signals.

Another example provides a motor (electrical motor, e.g. a brushless motor, an induction motor, or other motor) in combination with such motor control apparatus.

Another example provides control apparatus for controlling electrical apparatus, the control apparatus being adapted to implement a method in accordance with the first aspect, wherein said waveform is a waveform associated with operation of said electrical apparatus, the control apparatus being further adapted to generate a drive voltage, for application to a terminal of the electrical apparatus, in accordance with (i.e. from, or using) said one or more signals.

Another example provides electrical apparatus in combination with such control apparatus.

Another example provides a method of processing a data stream indicative of a waveform, the method comprising: processing the data stream to calculate a first stream of complex numbers indicative of a component of a transform of the data stream corresponding to an oscillating component of the waveform at a target frequency; transforming said first stream of complex numbers to produce a first output data stream (e.g. D phase output) and a second output data stream (e.g. Q phase output), the first output data stream being indicative of a first sinusoidal wave having said target frequency and having substantially the same phase and amplitude as said oscillating component, and the second output data stream being indicative of a second sinusoidal wave having said target frequency, having substantially the same amplitude as said oscillating component, and being substantially 90 degrees out of phase with said oscillating component.

In certain examples said transform is a Z transform.

In certain examples the method further comprises calculating an amplitude of said oscillating component from (using) the first output data stream and the second output data stream.

In certain examples the method further comprises calculating a shift in the phase of said oscillating component from (using) the second output data stream and said data stream indicative of said waveform.

In certain examples the method further comprises calculating a shift in the phase of said oscillating component from (using) the first output data stream, the second output data stream, and said data stream indicative of said waveform.

Thus, in certain examples, using the two outputs together one can calculate the amplitude. Using at least a single Q phase output and the single corresponding input data sample corresponding to this output, one can detect shifts in the phase of the input data. One can also use the D phase output to improve the quality of the phase measurement, as follows. Mathematically, if the data sample is ‘x’, the d phase output is ‘d’ and the q phase output is ‘q’, then the simplest phase measure that just uses the input and the Q phase output is ‘xq’; the improved measure is ‘xq−dq’.

Another example provides a method of controlling an electric motor having at least one drive coil (winding), the method comprising: generating a data stream indicative of a waveform corresponding to a current flowing in said drive coil; processing said data stream using a method in accordance with any above aspect; using the first output data stream and the second output data stream to generate a drive voltage; and applying said drive voltage to said drive coil.

Another example provides a method of controlling electrical apparatus, the method comprising: monitoring the apparatus to generate a data stream indicative of a waveform associated with an operation of the apparatus; processing the data stream using a method in accordance with any above aspect; using the first output data stream and the second output data stream to generate a control voltage; and applying said control voltage to the electrical apparatus to control said operation.

Another example provides a processing module for processing a data stream indicative of a waveform, the module comprising: a first input terminal for receiving said data stream; a second input terminal for receiving a signal indicative of a target frequency; a first output terminal; and a second output terminal, wherein the module is adapted to process said data stream to calculate a first stream of complex numbers indicative of a component of a transform of the data stream corresponding to an oscillating component of the waveform at said target frequency and transform said first stream of complex numbers to produce a first output data stream at said first output terminal, and a second output data stream at said second output terminal, the first output data stream being indicative of a first sinusoidal wave having said target frequency and having substantially the same phase and amplitude as said oscillating component, and the second output data stream being indicative of a second sinusoidal wave having said target frequency, having substantially the same amplitude as said oscillating component, and being substantially 90 degrees out of phase with said oscillating component.

In certain examples said transform is a Z transform.

In certain examples the module comprises a third input terminal for receiving an input determining a speed at which the output data streams respond to changes in at least one parameter of said waveform.

Thus, the module may comprise a third input port, such as that labelled w on the accompanying schematics. This port can also be set and adjusted in real time and it tunes how fast the iWave algorithm responds to changes in character of the input sine wave (particularly amplitude and phase). Generally, it takes about 1/w samples for the output of iWave to respond to changes in these parameters at the input. In certain examples the w input (third input) is fixed and one just tunes \Delta and feeds in data.

Another example provides control apparatus comprising such a processing module.

In certain examples the control apparatus comprises a phase lock loop comprising said processing module.

Another example provides such control apparatus in combination with an electric motor, the electric motor comprising a drive coil and the control apparatus being arranged to apply a drive voltage to said drive coil, wherein said waveform is indicative of a current flowing in said drive coil, and the control apparatus is adapted to generate said drive voltage according to said first and second output data streams.

Another example provides a method for recursively estimating at least one parameter of a first oscillating component of a sampled noisy input signal waveform, the method comprising: recursively generating from the sampled input signal a transform component corresponding to frequency-domain characteristics of the first oscillating component; transforming the transform component to yield one or more signals providing an indication of one or more of a frequency and an amplitude of the transform component; and estimating, from the one or more signals, one or more of a frequency, a relative phase and an amplitude parameter of the first oscillating component.

Another example provides a method for recursively generating from a sampled input signal an output data stream from which can be extracted frequency-domain characteristics of a first oscillating component of the sampled input signal which is within a controllable narrow bandwidth of a controllable frequency; transforming the output data stream to yield one or more signals providing an indication of one or more of a frequency and an amplitude of the oscillating component; and estimating, from the one or more signals, one or more of a frequency, a relative phase and an amplitude parameter of the first oscillating component.

### BRIEF DESCRIPTION OF THE DRAWINGS

Embodiments of the invention are further described hereinafter with reference to the accompanying drawings, in which:

FIG. 1 provides an illustration of a cosine wave and the locus of the component of its Z-transform at the wave frequency in the complex plane;

FIG. 2a provides a flow diagram of an example parameter estimation method in accordance with an example of the present invention;

FIG. 2b provides a schematic diagram of an apparatus configured to implement an example parameter estimation method in accordance with an example of the present invention.

FIG. 3 provides a schematic diagram of an Iterative Waveform Action-Angle Variable Estimator (iWAVE) module in accordance with the present invention;

FIG. 4 provides a schematic diagram of wave characterising system in accordance with an example of the present invention;

FIG. 5 provides a schematic diagram of an oscillator in accordance with an example of the present invention;

FIG. 6 provides a schematic diagram of an oscillator in accordance with an example of the present invention;

FIG. 7 provides a schematic diagram of an oscillator in accordance with an example of the present invention;

FIG. 8 provides a schematic diagram of a phase-locked loop in accordance with an example of the present invention;

FIG. 9 provides a schematic diagram of a phase-locked loop and wave canceller in accordance with an example of the present invention;

FIG. 10 provides a schematic diagram of a vector based electric motor controller;

FIG. 11 provides a schematic diagram of a synchronous electric motor controller in accordance with an example of the present invention;

FIG. 12 provides a schematic circuit diagram of an electric motor;

FIG. 13 provides a schematic diagram of an asynchronous electric motor controller in accordance with an example of the present invention;

FIG. 14 provides a schematic diagram of an asynchronous electric motor controller in accordance with an example of the present invention;

FIG. 15 provides a schematic diagram of an atomic force microscope in accordance with an example of the present invention;

FIG. 16 provides a schematic diagram of an electrical power generation control facility in accordance with an example of the present invention;

FIG. 17 provides a schematic diagram of a phase shift keying demodulator in accordance with an example of the present invention;

FIG. 18 provides a schematic diagram of a synchronous electric motor controller in accordance with an example of the present invention; and

FIG. 19 provides a schematic diagram of a resonant bandpass filter in accordance with an example of the present invention.

### DETAILED DESCRIPTION

### Waveform Characterisation and Parameter Estimation

The characterisation of an oscillating waveform, which may be a sinusoid hidden in noise for example, and subsequent estimation of the parameters in real-time or near real-time, is often required in a diverse range of fields such as physics, engineering, economics and statistics for example. Conventional techniques often utilise a discrete Fourier transform (DFT) to identify and then parameterise oscillating components in a sampled version of the signal of interest. However, as set out above, this can be a computationally inefficient approach in terms of the computations required but also memory requirements.

To mitigate the disadvantages associated with the use of existing techniques such as Fourier transforms for example, in accordance with an example of the present invention, a new wave characterisation technique is provided. The technique may be used to estimate parameters of any oscillating waveform but is particularly suited for use for estimating the parameters of a Fourier component or a periodic waveforms such as a sinusoid for example. The parameter estimation technique is based upon the half-range Z-transform given by

$${y}_{0} ( Σ ) = {\sum }_{n = - ∞}^{0} x ( n ) {e}^{n Σ} . \qquad ( 1 )$$

In Eq. (1) samples of a sampled input signal waveform or data stream representing a waveform sampled at a fixed or variable sampling rate are represented by x(n) where n=0 represents the sample most recently acquired, and increasingly negative n represent samples from further into the past. It is presumed that the input signal waveform it is sampled in accordance with the Nyquist sampling criterion, although this may not be essential. The input signal waveform x(n) may be real or imaginary/complex. The variable y₀(Σ) represents the output of the Z-transform and Σ represents a complex variable such that the sum converges for [symbol] (Σ)>0.

The connection between Eq. (1) and an oscillating component of interest is achieved by defining Σ=w−jΔ, where j=\sqrt{−1}, such that the argument of e^{nΣ} advances by a phase of Δ radians per data sample. The weighting of the samples with respect to their sample time i.e. n is determined by the real part of Σ, wherein 1/w is the number of elements in the past at which the element weighting has fallen off to 1/e˜1/2.72 of the weight of the most recent sample. For example, if the sampling rate of the input signal waveform is 256 Hz, and it is desired to track or parameterise an oscillation with a frequency of approximately 50 Hz (target frequency) with a reaction time to changes of 0.1 second, the variables would be set as Δ=2π×50/256=1.22 radians per sample for the frequency of the wave and 1/w=0.1*256=26 samples. However, the sampling rate, frequency and sampling weighting may take any required value depend on the nature of the wave and sampling rate. Furthermore, as is set out below in more detail, Δ may not be required to exactly correspond to the frequency of the oscillating component of interest.

The Z-transform given by Eq. (1) conventionally requires an infinite number of samples for a true representation of the sampled input signal waveform to be reached. However, more commonly a recursive Z-transform may be used in order to reduce both complexity, data record and memory requirements. Such a recursive Z-transform based upon Σ=w−jΔ is given by

$${y}_{0} ( Σ ) = x ( 0 ) + {e}^{- Σ} {\sum }_{n = - ∞}^{- 1} x ( n ) {e}^{( n + 1 ) Σ} = x ( 0 ) + {e}^{Σ} {y}_{- 1} ( Σ ) . \qquad ( 2 )$$

The variables in Eq. (2) have the same meaning as those in Eq. (1) though the transform sum has been broken up into two components and re-written in terms of the same transform calculated from the data available one sample earlier. The recursion relation of Eq. (2) may be rewritten as Eq. (3) below for a general input sample x(n) of the sampled input signal waveform

yₙ=xₙ+e^{-Σ}yₙ₋₁. (3)

The recursion expression Eq. (3) tends to the same quantity as the Z-transform coefficient at the same Σ when the number of data samples xₙ tends to infinity, and becomes an acceptable approximation to the Z-transform coefficient when the number of samples far exceeds 1/w. Furthermore, since the relation of Eq. (3) is equivalent to the Z-transform after the settling period of 1/w, Eq. (3) inherits the properties of the Z transform. For example, the Z-transform is linear, so if input data of Eq. (3) is scaled by any complex number, the output multiplies by that same scale in the steady state. Although described with reference the Z-transform, the iteration formulae of Eq. 3 is one of a more general class of iteration formulae of the form

$${y}_{n} = {\sum }_{p = 0}^{∞} {a}_{p} {e}^{jp Δ} {x}_{n - p} + {\sum }_{q = 1}^{∞} {b}_{q} {e}^{jq Δ} {y}_{n - q} \qquad ( 3 a )$$

where the coefficients aₚ and b_{q} are real, and correspond to the coefficients of a conventional real tap IIR filter fulfilling the usual conditions for the stability of the filter output and each of these coefficients is modified through multiplication by the phase factors shown [4]. The modified filters can be shown to share the stability of their real counterparts. The iteration algorithm of Eq. 3 is a special case where a₀=1, b₁=e^{-w}, and all other a and b coefficients are zero. Accordingly, Eq. 3a may be used to recursively generate estimates of transform components other than Z-transform components but which still include information that relates to the oscillating component of interest in the input signal. For example any transform or filter defined in accordance with Eq. 3a may be used to generate a transform component which provides information on frequency domain characteristics of the oscillation of interest or from which such information may be extracted. Consequently, although throughout this disclosure the parameter estimation technique is described with reference to the Z-transform, the technique is not limited to use with the Z-transform.

In many applications w may be significantly less than 1, meaning that the response time is significantly greater than the period between samples. In these cases, an approximation of e^{-w}≈1−w may be used. Also, by scaling the input xₙ by a factor of we^{jΔ} the transform output can be made to have the same order of magnitude as the input and both terms on the right hand side to share a common phase factor. These adjustments result in a scaled Z-transform iteration expression Eq. (4) valid for response times much longer than the sample period at which the input signal waveform is sampled

yₙ=e^{jΔ}(wxₙ+(1−w)yₙ₋₁). (4)

Although Eq. (4) represents an approximation of the Z-transform previously set out, its accuracy may be sufficient in circumstances other than those where the response time w is comparable to a sample period. However, in such circumstances the exact iteration expression Eq. (3) may be applied with little additional computational burden.

Eq. (1) to (4) present a computationally efficient half-range Z-transform adapted for used with oscillations with parameters approximately corresponding to Δ and w, such that a Z-transform component corresponding to an oscillation approximately defined by Δ and w is generated. The Z-transform component is comprised by a stream of complex numbers, where each transformed sample is represented as a complex number. However, in order to characterise the oscillation of interest, information is required to be extracted from the Z-transform component. Parameter estimation of one or more of the amplitude, frequency and phase associated with the oscillation of the sampled input signal waveform may then be performed using the extracted information. Although, the outputs of Eq. (2) to (4) are represented as complex numbers throughout this disclosure, these equations may also be represented as single input, two output filters where both the input and outputs are real numbers.

As well as representing the reciprocal of the number of samples in which the Z-transform responds to changes in the input i.e. a weighting or averaging variable where a longer averaging period results in decreased noise but a slower response time (decreasing w increases lookback time), w may also be interpreted as the bandwidth of the Z-transform in units of radians per sample, in the same way as Δ is the oscillation frequency of interest in radians per sample. For example, with a frequency of 256 Hz and a response time of 0.1 s, oscillations in a frequency range of 246 Hz to 266 Hz may be represented by the output of the Z-transform. The variables Δ and w may be fixed, and determined prior to each recursion of the Z-transform or updated when necessary based on knowledge of the oscillating component which is to be characterised. For example, if the frequency of the oscillating component is known to change, Δ may be adjusted to f/(2πτₛ), where f is the new frequency. In particular, if the time delay between the latest sample and the previous one is tₛ, then Δ is 2πftₛ with f the oscillation frequency in Hz, and w is the ratio of tₛ to the desired response time. Adjustments may also be made to w and Δ each sample to allow for variations in tₛ, thus allowing the Z-transform to operate with data at variable sampling rates.

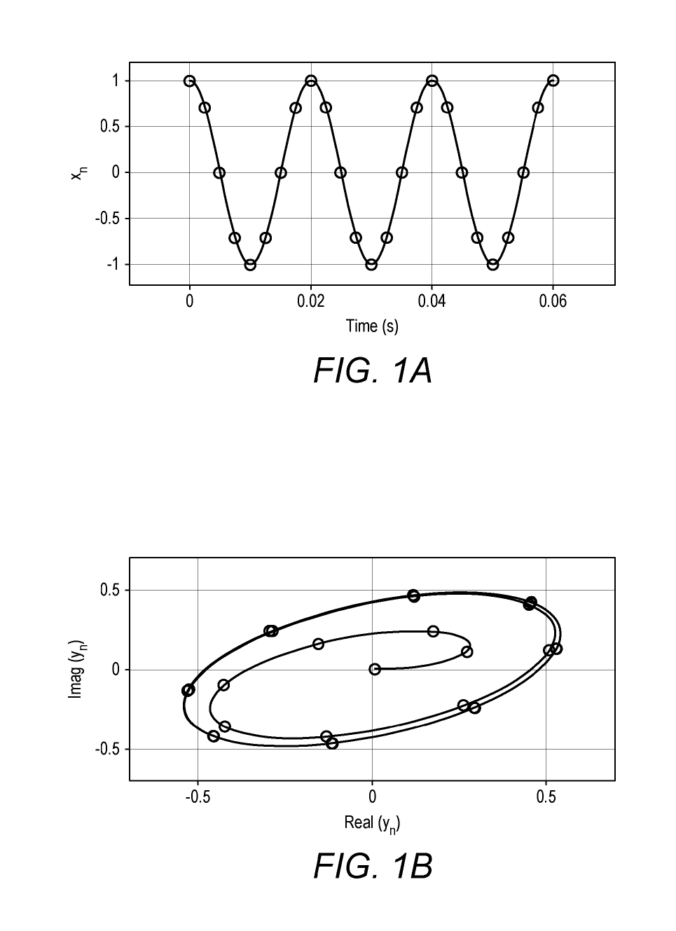

We next discuss the case where the input signal x(n) is real. The steady-state response of a Z-transform to a real sinusoidal input is an elliptical trajectory in the complex plane. FIG. 1b shows the trajectory in the complex plane (i.e. the real and imaginary values) of the output of Eq. (4) when samples representing three cycles of the 50 Hz cosine wave shown in FIG. 1a with a sampling rate of 256 Hz are input into Eq. 4, where w=0.1, so the response time is 1/w=10 samples, which at 50 Hz is about 2 cycles of the wave, and a phase shift per sample Δ corresponding to 50 Hz. During the first three cycles of the sine wave, the recursive algorithm output starts at zero and then spirals outwards. As time progresses and with a continuing sinusoidal input, the output would tend to its steady state response of an elliptical trajectory. Therefore, the response trajectory cycles outward from the origin as the samples are fed in, and in practice tends to an ellipse towards three or more cycles.

In accordance with an example of the present invention, signals providing an indication of characteristics of an oscillation included in the samples input signal may be extracted via plotting the trajectory in the complex plane of the Z-transform of the sampled oscillation. To achieve this extraction, the output of the Z-transform may be transformed to yield quantities that may be referred to action-angle variables. Further information on action-angle variables may be found in [3].

An angle variable is a quantity that monotonically increases sharing the period and phase of a periodic system it is representing as it evolves. An action variable is one that yields a measure of the stored total energy in a system. In terms of an oscillation such as a sinusoid, the phase of the oscillation is a suitable angle variable, and the square of the amplitude of the oscillation is a suitable action variable [3]. For non-sinusoidal waves, the angle variable may be taken to be the phase of the fundamental sinusoid where the nth harmonic sinusoid will have a phase that varies n times as rapidly with increasing time as the fundamental.

With respect to the Z-transform of the input signal waveform illustrated in FIGS. 1a and 1b, it is necessary to establish an equation of the ellipse in order to extract the angle and action variables and estimate the parameters of the underlying oscillation. To establish such an equation, the input signal waveform is presumed to be a cosine wave defined as cos(nΔ). This cosine wave may then be decomposed into two phasors rotating in opposite directions, xₙ^{f}=e^{jnΔ}/2 and xₙ^{b}=e^{-jnΔ}/2.

By assuming that the response to these phasors will be of the form yₙ^{f}=a^{f}e^{jnΔ+jφ}^{_{f}} and yₙ^{b}=a^{b}e^{-jnΔ+jφ}^{_{b}}, where a^{f} and a^{b} are the real amplitudes of the output phasors for the two phasor inputs, and φ_{f} and φ_{b} are the phase shifts between the input and output phasors, and by substituting the phasors into Eq. (3), the parameters can be shown to take the following values

$$\begin{matrix}{a}^{f} = \frac{1}{2} & ( 5 ) \\ {φ}_{f} = 0 & ( 6 ) \\ {a}^{b} = \frac{1}{2 \sqrt{1 + {e}^{- 2 w} - 2 {e}^{- w} cos ( 2 Δ )}} & ( 7 ) \\ {φ}_{b} = {tan}^{- 1} ( \frac{sin ( 2 Δ )}{{e}^{w} - cos ( 2 Δ )} ) . & ( 8 )\end{matrix}$$

For the case of approximate recursions such as that of Eq. (4), each factor of e^{±w} may be expanded such that the overall expressions are correct to the desired order in w. For the specific case of Eq. (4), the input has been pre-scaled by a factor of we^{jΔ}, which adds a phase delay of Δ to Eq. (6) and Eq. (8) and scales the amplitudes of Eq. (5) and Eq. (7) by a factor of w.

The output yₙ is the sum of the responses to the two phasor inputs, yₙ=yₙ^{f}+yₙ^{b}. Defining α=(φ_{f}−φ_{b})/2 and β=(φ_{f}+φ_{b})/2, we can write this output as

yₙ=e^{jβ}(a^{f}e^{j(nΔ+α)}+a^{b}e^{-j(nΔ+α)}). (9)

In terms of sinusoids, this can be written as

yₙ=e^{iβ}((a^{f}+a^{b})cos(nΔ+α)+j(a^{f}−a^{b})sin(nΔ+α)). (10)

Eq. (10) represents the steady-state response of Eq. (3) to a cosine wave stimulus. More specifically, Eq. (10) is an equation of an ellipse having semi-major axis (a^{f}+a^{b}) and semi-minor axis (a^{f}−a^{b}), with the semi-major axis inclined at an angle β to the real axis. Furthermore, when the input wave is at zero phase, the argument of the equation output yₙ minus the argument of the semi-major axis of the ellipse is the angle β.

To obtain the aforementioned action-angle variables, which represent the amplitude and phase of an input oscillation, each instance of the output yₙ may be transformed according to a transform that takes into account the values of a, α and β.

In terms of the ellipse shown in FIG. 1B, to perform the transform, firstly the ellipse is rotated through an angle—β to align the semi-major axis with the real axis and the semi-minor axis with the imaginary axis. Secondly, the ellipse is sheer transformed parallel to the real and imaginary axes to deform or map the ellipse to a circle of an amplitude equal to the oscillation amplitude. Lastly, the circle is rotated through an angle—α such that when the input oscillation is at a zero of phase, the argument of the output is zero such that the substantially circular locus so as to have an argument substantially equal to the phase of the first oscillating component.

With regard to the individual samples output from the Z-transform, each of these three steps can be realised by the multiplication of a 2×2 matrix by the output of the step before, with the first step operating on a column vector whose elements are the real and imaginary parts of yₙ.

The predetermined transform is defined by expression of Eq. (11) below, where the input value yₙ is transformed through the three steps to form output value zₙ, where zₙ^{R} represents real part and zₙ^{I} represents the imaginary part of zₙ.

$$( \begin{matrix}{z}_{n}^{R} \\ {z}_{n}^{I}\end{matrix} ) = ( \begin{matrix}cos α & sin α \\ - sin α & cos α\end{matrix} ) ( \begin{matrix}\frac{1}{{a}^{f} + {a}^{b}} & 0 \\ 0 & \frac{1}{{a}^{f} - {a}^{b}}\end{matrix} ) ( \begin{matrix}cos β & sin β \\ - sin β & cos β\end{matrix} ) ( \begin{matrix} ( {y}_{n} ) \\ ( {y}_{n} )\end{matrix} ) \qquad ( 11 )$$

Although the transform has been defined with respect to three separate steps, the transform may be applied by simply performing the matrix multiplications set out above. In other examples, one or more of the steps may not be necessary, for example rotation of the circle may not be necessary if the phases are already aligned or the sheer transform of the locus may not be necessary if the locus is already substantially circular. In such cases, one or more steps of the transform may not be performed. In terms of Eq. (11) a transform step is not required if one of the three 2×2 matrices is an identity matrix. However, the three 2×2 matrices may also be multiplied together to give one overall transformation matrix for the sake of computational efficiency and the resulting matrix used to apply the transform applied via a single matrix multiplication. In other examples the transform steps set out above may be performed in a different order. However, unless the matrices representing the transform commute, the steps of the transform may require alteration.

In terms of the input signal waveform or oscillation being a sinusoid, each samples of the input data streams results in a complex number, and these complex number form a locus of a circle centred on the origin having radius equal to the amplitude of the oscillation and an argument equal to the phase of the oscillation comprised by the input signal waveform. The action and angle variables Aₙ and φₙ for the oscillation are equal to the modulus and argument of the complex number zₙ, where Aₙ and φₙ are given by Eq. (12) and Eq. (13) below, respectively, and if the input to the transform is a cosine wave, the projection of the locus of zₙ onto the real axis is also a cosine wave and the projection of the locus of zₙ onto the imaginary axis is a sine wave.

Aₙ=\sqrt{zₙ^{R}^{²}+zₙ^{I}^{²}} (12)

φₙ=Pr(arg(zₙ)), (13)

where in practice Pr(arg(zₙ)) is evaluated with the a tan 2 function available in many real mathematical function computer libraries, where the function a tan 2(zₙ^{I},zₙ^{R}) returns the principle value of the argument of zₙ.

Through the successive input of samples an input signal waveform into the Z-transform and their subsequent transformation to reach the action-angle variable, the output of the transformation expression Eq. 11 forms one or more signals or data streams which take the form of sinusoidal waves. From these waves, estimates of the amplitude, phase and frequency of an oscillation in the input signal waveform within the bandwidth of the frequency defined by Δ may be calculated using Eq. (12) and (13). More specifically, the waves correspond to the real and imaginary parts of zₙ, where, when the oscillation is a cosine, a first wave (D phase wave) formed from zₙ^{R} will be in phase with the oscillation and a second wave (Q phase wave) formed from zₙ^{I} will be

$$\frac{π}{2}$$

out of phase with the oscillation. The frequency and amplitude of the first and second waves correspond to the frequency of the oscillation comprised by the input signal waveform and an estimate of the amplitude of the input oscillation may be calculated from any samples by taking the modulus of zₙ or adding correspond samples of the D and Q phase outputs in quadrature and the taking the square root of the answer. The phase, or more accurately the relative phase or phase shift, of the input oscillation may be approximated by multiplication of the input signal and the Q phase output. However, as is explained in more detail below with reference to FIG. 4, an improved approximation of is obtained by subsequently subtracting the product of the sampled input signal and the D phase output.

The procedure defined by Eq. (3) and Eq. (11) provides an efficient method for the calculation of values that may then be used for estimation of amplitude, phase and frequency of an oscillating component in an input signal waveform. Although, the procedure described up to this point has assumed an input signal waveform comprised by an ideal sinusoid with no noise component, as will be described in more detail below, using the technique defined by Eq. (3) and Eq. (11), the parameters of sinusoids hidden in noisy data may also be estimated using this method.

This procedure may considered to be an Iterative Waveform Action-Angle Variable Estimator (iWAVE) and therefore the process defined by Eq. (3) and Eq. (11) will referred to from this point onwards as iWAVE.

As described above, iWAVE presumes that oscillations of interest are predominantly sinusoidal. In combination with the use of the response time w, the phase, amplitude and frequency represented by the D and Q phase waves are therefore effectively a weighted average of the values of these parameters of the input oscillation over the response time of iWAVE. Consequently, iWAVE naturally provides noise rejection since it rejects noise outside the iWAVE bandwidth w/(2πτₛ) about the iWAVE frequency Δ/(2πτₛ). Furthermore, noise rejection may be increased by increasing the response time (decreasing w), which results in a longer lookback/averaging time.

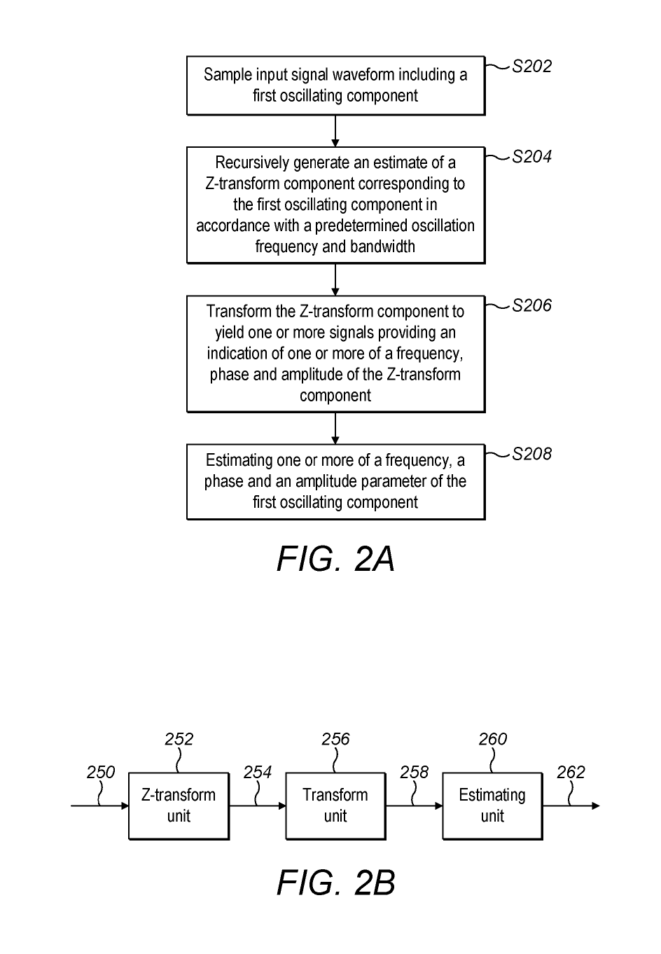

FIG. 2a provides a flow diagram summarising steps comprised by a procedure in which one or more parameters of an oscillating component of an input signal waveform are estimated using iWAVE.

Initially, at step S202 an input signal waveform which includes at least a first oscillating component is sampled at a sampling frequency that may either be fixed or variable.

At step S204 a Z-transform component corresponding to the first oscillating component is generated using the recursive Z-transform of Eq. 3 in accordance with a predetermined or target frequency Δ/(2πτₛ) and a bandwidth w/(2πτₛ). The predetermined frequency is an initial estimate of the frequency of the first oscillating component and the first oscillating component will be captured by the Z-transform if its frequency falls within the bandwidth around the predetermined or target frequency.

At step S206, following the generation of the Z-transform component, the Z-transform component is transformed according to Eq. 11 to provide samples of one or more signals zₙ^{I}, zₙ^{R} which provide an indication or at least one of a frequency, amplitude and phase of first oscillating component as set out above.

At step S208 estimates of one or more of the amplitude, frequency and phase of the first oscillating component are performed based on the one or more signals (D and Q phase waves).

Although FIG. 2a illustrates the four steps being performed immediately after one another, the steps may also be performed separately. For example, S202 may be performed separately to steps S204 to S208 such that pre-sampled data is input into step S204. Likewise, estimating the amplitude, phase and frequency may be performed once a plurality of samples which form the D and Q phase waves are known.

FIG. 2b provides an illustration of an apparatus for implementing parameter estimation using iWAVE. A sampled input signal including a first oscillating component is input at 250 into a Z-transform unit 252. The Z-transform unit is configured to recursively generate an estimate of a Z-transform component corresponding to the first oscillating component in accordance with the predetermined oscillation frequency and bandwidth. The generated Z-transform component is then input at 254 into a transform unit 256. The transform unit is configured to transform the Z-transform component in accordance with one or more of the matrices of Eq. 11 to yield one or more signals (D and Q phase waves) which provide an indication of one or more a frequency, phase and amplitude of the Z-transform component and thus the first oscillating component. The D and Q phase waves are then input at 258 into an estimating unit 260. The estimating unit is configured to estimate one or more of a frequency parameter, a relative phase and an amplitude parameter of the first oscillating component which are then output at 262. Although the apparatus is shown to include an estimating unit, in some examples only the Z-transform unit and the transform unit may be required since the D and Q phase waves output by the transform unit at 258 may be utilised in a manner different than providing direct estimation of parameters of the first oscillating component.

The input parameters Δ and w may be varied depending on additional information on the oscillation which is being parameterised. For example, by virtue of the frequency estimation based on the D and Q phase waves, more accurate knowledge of the oscillation of interest may be obtained and, Δ and/or w can be varied accordingly for one or more subsequent iterations of the procedure. Added to this, since the input parameters are easily varied, a sampling rate of the input signal waveform which is inconsistent or variable may be taken account of by varying the input parameters accordingly. For example, if samples of a signal are not received or are irregularly spaced, which may be the case when samples are wireless transmitted or data is unavailable for another reasons for instance, the effective sampling rate may change. For instance, if alternate samples are not received by iWAVE, the sampling rate is effectively halved. However this change in effective sampling rate may be compensated for by doubling Δ. This therefore enables iWAVE to characterise oscillations in wide range of scenarios where interruptions to data are likely and which conventional estimation techniques may find problematic. Furthermore, iWAVE may also be applied to scenarios where sampling rates varying for other reasons. For instance, iWAVE may be suited for use in a digital system where sampling rates may be reduced or increased when power consumption or accuracy are required to be reduced and increased, respectively depending on the conditions under which the system is operating. For example, if an increase signal-to-noise ratio (SNR) or signal to interference and noise ratio (SINR) is required, which may be the case if the noise and/or interference in a channel increases, the response time may be increased so that estimated qualities are effectively averaged over a longer period and thus noise suppression increased.

The iWAVE procedure has been described up to this point predominantly with reference to an input signal waveform consisting of a single oscillating component. In the case where there is more than one oscillating component, an iWAVE algorithm can first be applied to one of the oscillating components, and the D-phase output of iWAVE subtracted from the input data, resulting in a residual dataset containing one less oscillating component. This procedure can be applied iteratively. Each iWAVE algorithm should have w and Δ set so that such that each algorithm is centred on or targeted at a single oscillation (Δ=2πτₛ) and has negligible overlap with the other oscillating components (w<<2πΔfτₛ) where Δf is the frequency gap to the nearest neighbour sinusoid in frequency space). Alternatively, the iWAVE algorithms can be applied in parallel to the input data, each one operating separately on a separate oscillation. Or, any combination of serial and parallel applications of iWAVE is also possible. In some examples, the input signal waveform may contain one or more oscillations whose frequency is non-stationary. In this case, an element of feedback may be used to form an iWAVE-based phase-locked loop. iWAVE-based phase-locked loops are discussed in more detail below.

The iWAVE technique described above with reference to FIGS. 1 and 2 provides a procedure for generating one or more waves which represent an oscillation or Fourier component in an input signal waveform. The complexity and memory requirements of this procedure are reduced compared to performing a conventional DFT since, by virtue of the recursion relation of Eq. (3), at a minimum only one complex value is required to be stored from one iteration of the procedure to another, and a reduced number of complex additions and multiplications are required compared to a DFT. Furthermore, since the present technique does not provide parameterisation based on frequency intervals or bins, unlike a DFT based approach, interpolation is not required to achieve parameterisation of a particular frequency component of signal.

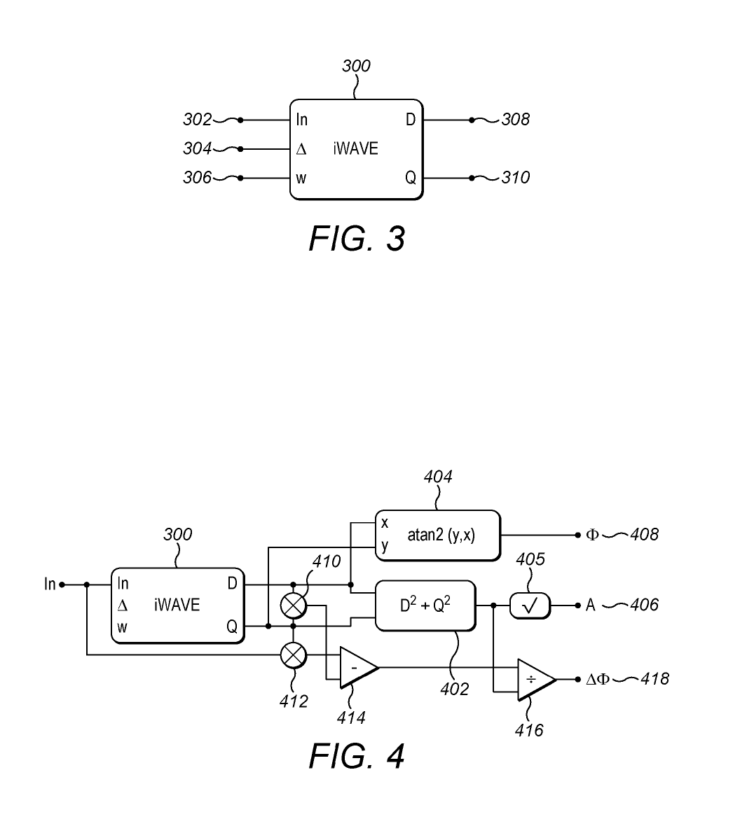

FIG. 3 provides a schematic diagram of an iWAVE element 300 which represents an apparatus for performing the processes performed by Eq. (3) and (11) and the inputs and outputs to these equations. Each sample of an input waveform is successively input into the iWAVE at port 302 and the input parameters Δ and w are input at points 304 and 306, respectively. The D phase and Q phase outputs 308 310 for each input sample are the real zₙ^{R} and imaginary zₙ^{I} parts of zₙ and correspond to the samples of the aforementioned D and Q phase waves. The outputs waves may then be formed by successively passing samples from an input signal waveform though the iWAVE module. Although FIG. 3 illustrates that samples representing both D and Q phase waves are output, in some examples only the D or only the Q phase wave samples may be output.

Although the input variables Δ and w have defined in units of radians per samples and seconds, they may also be input in any appropriate unit but may then require subsequent conversion to the units suited for the Z-transform of Eq. 3. For example, Δ may be derived from a frequency input f in Hz, where Δ=2πfτₛ, and w may be derived from a bandwidth B in Hz, where B=2πwτₛ. In both cases, τₛ is the sampling period of the input data.

### Wave Tracking

In accordance with an example of the present invention, iWAVE may be used to characterise an oscillating component of an input signal waveform which is static or varies in one or more of frequency, phase or amplitude such that the oscillating component is tracked.

FIG. 4 shows a configuration of iWAVE suitable for estimating the characteristics of an oscillating component whose frequency is static in terms of amplitude and phase, where static in the context of iWAVE means that it is within a bandwidth of w/2πτ_{S} Hz about the set frequency of Δ/2πτ_{S} Hz. The D phase and Q phase outputs are squared and the resultant squares added together by unit 402. The square root of the result output by unit 402 is then taken by the square root unit 405. The output of square root unit 405 is then an estimate of the amplitude of the oscillation. The D and Q phase outputs are fed to the arctangent unit 404 which performs the calculation a tan 2(Q, D) to estimate the phase Φ of the oscillation which is then output at port 408.

The output A is the square root of the estimate of the action variable of the oscillation, and the output Φ is the estimate of the angle variable. If the oscillating component of the input signal waveform at the input of iWAVE is a sine wave, then A is a constant and Φ is a ramp waveform having a constant gradient equal to 2π times the frequency of the waveform, with discontinuities at the branch cuts of the principle value function that reset the ramp to its value just after the previous branch cut discontinuity, thereby ensuring that Φ is periodic with the same periodicity as the oscillation. The zero of phase may be defined anywhere on the ramp, but it is often conventional to define zero phase either at the bottom of the ramp or half way up it. Although various functional units have been illustrated as individual units, they may also be implemented in any equivalent manner.

iWAVE has a response time of w⁻¹ samples, therefore fluctuations in the amplitude or phase of the input data on a timescale substantially less than w⁻¹ samples may not significantly change these outputs. As previously mentioned, iWAVE may therefore be viewed as having a memory for the average state of the oscillating component over order of w⁻¹ samples. Consequently, a detector for detecting abrupt shifts in the rate of increase of phase in the oscillation of interest in input data may be achieved by mixing the input data with the Q phase output of iWAVE. Such a detector is effectively a homodyne detector for detecting shifts in the rate of phase accumulation in the input waveform.

An example of homodyne detection is illustrated in FIG. 4, where the homodyne detector is formed from mixers 410 and 412, subtraction unit 416 and division unit 416. Firstly the input signal is mixed with the Q phase output. The resulting mixer output has two components, a DC shift proportional to the size of the phase shift between the input signal and the Q phase output and a component at twice the wave frequency due to beating of the wave in the input data against the wave at the Q phase output. Next, by subtracting the product of the D and Q phase outputs formed by mixer 410 from the output of mixer 412 using subtracting unit 414, much of the second harmonic contamination resulting from the mixing of mixer 41 is removed. The output from the subtraction unit 414 is then divided by the square of the wave amplitude, since both the data input and the Q-phase output of iWAVE scale as the wave amplitude and we wish to decouple phase excursions from amplitude fluctuations. A DC component corresponding to the phase shift between the input and the output of iWAVE is then output at the output 418 (ΔΦ). This phase shift detector allows the phase of a signal to be tracked over time by comparing its instantaneous phase with its average phase of the response time of iWAVE. As is explained in more detail below, the phase difference ΔΦ between the input and the average phase of the oscillation in interest may be utilised as part of a phase-locked loop capable of tracking oscillations with changing frequency. The ability of iWAVE to extract a phase of a signal and phase difference or change with respect to an input oscillation signal with respect to a single input makes iWAVE an attractive candidate for application where phase extraction of a physical systems is required since only one sensor or measurement point may be required to provide information on phase. This may in turn lead to reduced costs and increased reliability due to a reduction in sensor numbers. These advantageous are discussed in more detail below. Although a particular example of a homodyne detector is illustrated in FIG. 4, there are numerous other homodyne detector implementations that may be used. For example, the second harmonic may be partially or fully cancelled via the use of a second iWAVE unit configured to characterise the harmonic component, a separate conventional filter, or may simply be ignored in some instances.

As set out above, in addition to operating on input signal sampled at a fixed sampling rate, iWAVE may also operate with data which has been sampled at a variable sampling rate or has an effective sampling rate which varies with time. In order to account for varying sampling rates, w and/or Δ may be adapted according to the current effective sampling rate of in the input signal. For example, FIG. 4 may additionally include a sampling rate analyser which determines or otherwise obtains a current sampling rate of the input signal and adapts w and/or Δ based on one or more of the sampling rate, response time of the algorithm and the frequency of the oscillating component of interest.

### Oscillators

The transfer function of iWAVE between the IN and D phase ports is resonant at a frequency of Δ/2πτ_{S} Hz. The bandwidth of this resonance in Hz is the reciprocal of the response time of the filter divided by 2π, or w/2πτ_{S} Hz. iWAVE may therefore be utilised to form an oscillator with controllable phase and frequency by feeding the D phase output back to the IN port with no phase shift, thus satisfying the Nyquist stability criterion for a stable oscillator since the D phase output will be approximately in phase with signal input into the IN port. Further background information on oscillators can be found in [2].

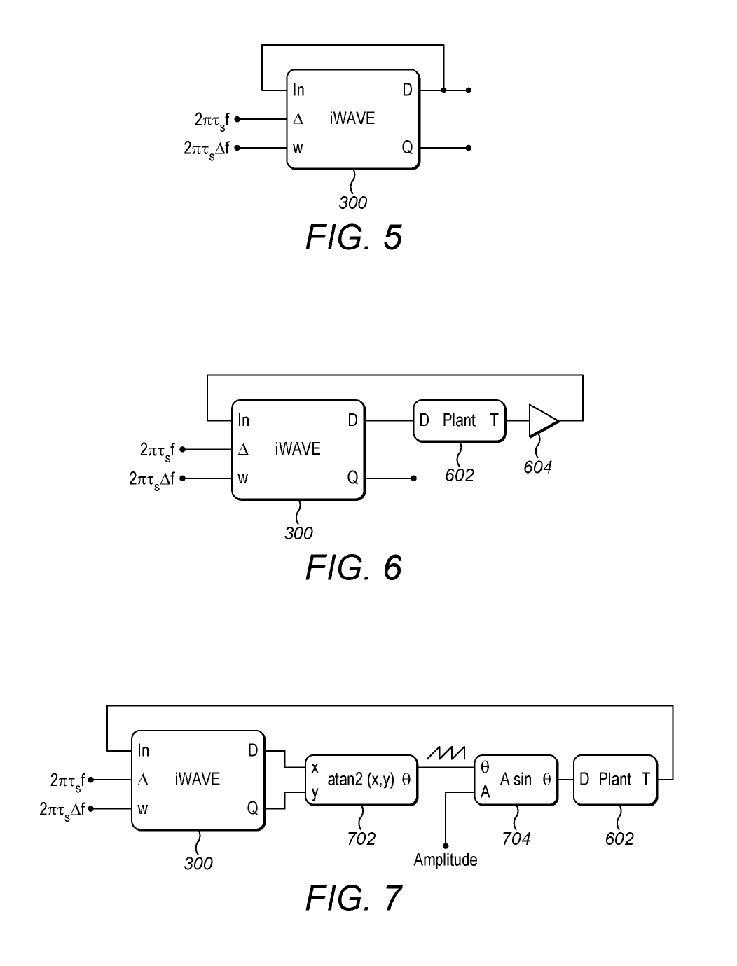

An example oscillator based upon iWAVE is illustrated in FIG. 5, where the frequency and phase of the resulting oscillator can be controlled by adjusting the values of the parameters Δ and w. To form the oscillator, the D phase output of the iWAVE is used as feedback to the input port thus providing the positive feedback required for forming an oscillator. Any initial non-zero input into the input port will thus cause the iWAVE to oscillate according to Δ=2πτₛf and w=2πτₛΔf where is the oscillation frequency.

FIG. 5 presents a basic oscillator for the generation of a stable frequency. FIG. 6 illustrates a variant of the oscillator of FIG. 5, where the purpose is to cause a controlled oscillation of an external, non-resonant plant 602. In this configuration the resonant character of iWAVE causes the plant to oscillate sympathetically.

The plant includes some form of transducer which can be used to feed the iWAVE input. The iWAVE D phase output is then used to drive an actuator which induces the plant to oscillate in a manner such that it is in phase with the transducer. When using conventional techniques, it is frequently presumed that the amplitude of the transducer signal contains no useable information. However, iWAVE can infer the phase of the oscillator from a sinusoidal waveform alone. This phase can be used to drive a secondary oscillator, or the D output can itself be used to drive the non-resonant plant. The plant may be mechanical, electronic, or of any other form where a proportional generalised displacement can be induced by a suitable actuator and the resulting displacement can be detected by a suitable transducer.

The T output of the non-resonant plant 602 represents a transducer that produces a signal proportional to the oscillation induced in the plant. The D input is a drive proportional to the applied signal. Preferably the transducer is arranged so that it is in phase with the desired drive waveform, but may not required if the phase shift between the transducer output and the desired drive waveform is known. The amplifier 604 allows the drive oscillation amplitude to be scaled so that the open loop gain between the input to iWAVE and the amplifier output is +1 to satisfy the Nyquist stability criterion.

FIG. 7 illustrates a further iWAVE based oscillator, in which the iWAVE oscillator is coupled to non-resonant plant where the outputs of iWAVE are combined by a an arctangent unit 702 to yield an angle variable that drives a secondary oscillator 704 with a separate drive amplitude control input A. In the case of FIG. 7, the secondary oscillator 704 is a unit providing a sin function scaled by amplitude A. This step breaks the loop dependence on the magnitude of the open loop gain, since part of the loop only contains an angle variable which is guaranteed always to produce the same amplitude signal in the secondary oscillator. As for the oscillators of FIGS. 5 and 6, the frequency and phase of the oscillator in FIG. 7 may be tuned via adjusting Δ and w in accordance with Δ=2πτₛf and w=2πτₛΔf.

The use of iWAVE to form an oscillator enables a computationally efficient and reliable oscillator to be formed from a general wave characterisation module. Consequently, multiple instance of iWAVE may be formed on a semiconductor chip which may either be a general programmable processor or an application specific integrated circuit. These multiple instances may then be used to both monitor the behaviour of a system/plant and also drive the system without the need for relatively complex Fourier based frequency analysis.

### Phase-Locked Loops

The ability for iWAVE to form both oscillators and wave characterisation apparatus make it a suitable candidate for the formation of a phase-locked loop (PLL) since these are the two fundamental features of a phase-locked loop.

A phase-locked loop is a common means by which the frequency and phase of a waveform may be tracked. A phase-locked loop conventionally comprises a variable frequency or reference oscillator and a phase detector or phase comparison circuit which compares the phase of the oscillator output and that of the signal which is to be tracked. The variable oscillator is then adjusted dependent upon the result of the phase comparison. For example, if the signal to be tracked has a phase lead compared to the variable oscillator, the frequency of the variable oscillator may then be increased and vice versa. Subsequently, as long as the signal to be tracked does not jump beyond the useful bandwidth of the frequency tracking loop in frequency, the reference oscillator will track the signal as it varies in both frequency and phase.

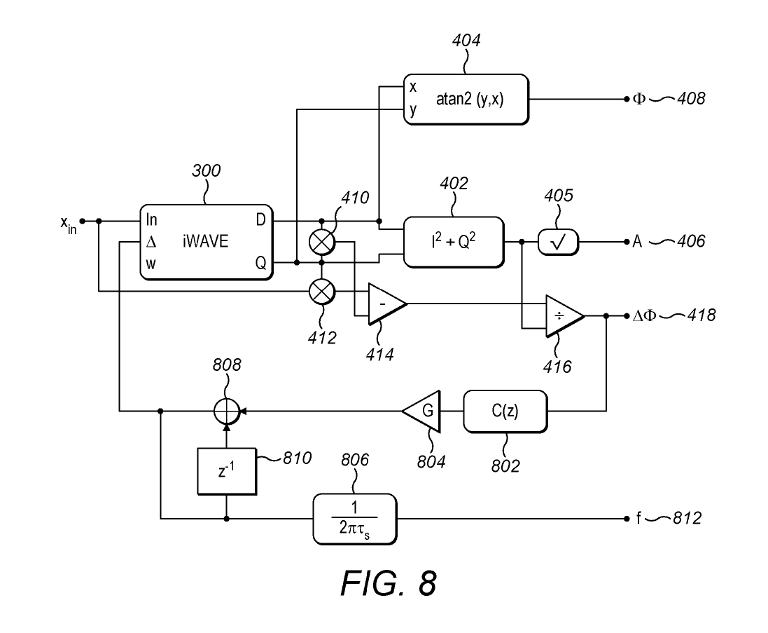

FIG. 8 illustrates a phase-locked loop in which iWAVE provides the functionality conventionally provided by a reference oscillator and a phase comparator. The structure of the phase-locked loop is therefore similar to that of FIGS. 4 and 5 and thus units of FIG. 8 similar to those of FIGS. 4 and 5 will not be described in detail. In FIG. 8, since the D phase and Q phase outputs of iWAVE reflect the average oscillatory behaviour of the input data over a timescale of order τₛ/w seconds, the outputs of iWAVE may be used as a reference. Accordingly, if the input wave changes its frequency, this will result in an accumulating phase difference between the wave at the D phase output of iWAVE and the input data in similar manner to the system of FIG. 4. The ΔΦ output from the homodyne detector may then be used as an error signal for control of the WAVE oscillating frequency. In particular, if the instantaneous phase of the input wave climbs faster than the rate expected for the current frequency, a DC offset will appear in the homodyne detector resulting in a DC component to ΔΦ. This error signal is fed back through a control filter 802 followed by a feedback gain unit or amplifier 804 to form a signal which is added by an addition unit 808 to the iWAVE phase shift per sample from the previous sample, where the previous phase shift per samples has been delay by one sample by a delay unit 808. The output from the addition unit 808 may then be inputted into the Δ input of iWAVE, thus altering the frequency to be tracked. The control filter 802 can take many forms, for example maximal flatness of the frequency response of the phase-locked loop and matching of the bandwidth of the phase-locked loop to the frequency response of the ΔΦ output to frequency fluctuations is one such choice that may be used to determine the feedback and gain parameters. Likewise, although the various operational blocks in FIG. 8 have been illustrated as being discrete units, in some examples their functionality may be incorporated into one or more functional units, incorporated onto a single integrated circuit or their functionality may not be required.

If the phase-locked loop remains locked, the current frequency f in Hz is output at 812 and is given by the feedback control signal Δ divided by 2πτₛ, which in FIG. 8 is performed by the division unit 806. The phase-locked loop configuration of iWAVE is applicable to devices where the wave frequency may drift in an unpredictable manner. For example, in an electric induction motor, the currents in the drive wires to the motor contain two components, one at the frequency of the drive, which is known, and the other at the frequency of rotation of the motor, which is not known and is dependent on the motor load. Alternatively, in a wireless receiver a carrier frequency may vary due to drift in the oscillator at the transmitter and thus a phase-locked loop as illustrated in FIG. 8 may be used to track the carrier frequency of the received signal and subsequently demodulate the received signals.

As briefly discussed above, if the input signal waveform were to include a plurality of sinusoidal oscillations within the bandwidth of iWAVE, the D and Q phase outputs will predominantly represent the oscillation with the largest amplitude. Therefore this will be the signal which is locked upon by the phase-locked loop. In the case where the oscillation to be tracked is hidden by a dominant waveform, the dominant oscillation may first be tracked and then subtracted from the input signal waveform and then the desired oscillation tracked in the augmented input signal waveform. This process is discussed in more detail below.

In examples where the phase-locked loop is closed by connecting the feedback signal from the output of 804 to the Δ input of iWAVE unit 300, and there are multiple sinusoids present in the data, iWAVE may be configured to lock on to one of the signals. To achieve this, the bandwidth Δf should be set to be less than the anticipated frequency difference between adjacent sinusoids, or it may attempt to lock to multiple sinusoids at once or simply lock onto the sinusoid with the largest amplitude, both of which are liable to lead to a less accurate characterisation of the sinusoid of interest. Even though the bandwidth of iWAVE, when locked, may be significantly less than the initial difference between the iWAVE set frequency Δ/2πtₛ, experience has shown that an initially unlocked iWAVE algorithm will frequently catch lock, that is, Δ will adjust through the closed loop feedback until it is related to a sinusoid in the input signal by Δ=2πfτₛ. The robustness of the phase-locked loop is due in part to the fact that there is only one free parameter in the feedback system—the frequency of the sinusoid. As alluded to earlier, conventional phase-locked loops contain a reference oscillator whose frequency and phase with respect to wave to be tracked are both initially unknown. Both of these parameters have to be within some tolerance simultaneously for phase lock to be achieved. Because iWAVE uses the data itself to generate the internal action-angle variable representation, the angle variable is constrained to be the phase of the wave in the data; it is only the frequency that has to be correct. The small set of initially unknown parameters (frequency) in iWAVE compared to the larger set (frequency and phase) of initially unknown parameters in a conventional phase-locked loop is a tangible advantage of iWAVE implemented as a phase-locked loop.

The exact properties of the iWAVE phase-locked loop depends on the choice of feedback control filter C(z) 802. Though many choices are possible, in one example a filter consisting of a single real pole at s=−½τₛ and a single real zero at s=−1/τ₂, where τ₂ and the feedback gain G in the feedback path are related to the response time τ=τₛ/w by

$$\begin{matrix}\frac{\sqrt{G}}{{τ}_{s}} = \frac{1}{τ} , & ( 14 ) \\ {τ}_{2} = τ ( \sqrt{2} - 1 ) & ( 15 )\end{matrix}$$

may be used. These choices leads to a closed loop response of the phase-locked loop that is maximally flat up to a cutoff frequency of ½πτ.

It may prove advantageous in some cases to vary the bandwidth w/2πτₛ dynamically based on a measurement related to the system. For example, in the case of induction motors, as the motor approaches the zero-torque limit where the rotation rate approaches the drive frequency, it may be necessary to reduce w (and hence increase the response time to changes in frequency), so that the possibility that the iWAVE instance tracking the rotation rate starts to track a component due to the sinusoidal drive signal. But, when the motor is more heavily loaded, for example when it is starting up, the rotor frequency may vary more rapidly, and in these circumstances, w may need to be larger to ensure that iWAVE can remain locked as the rotor speed varies.

### Signal Cancellation

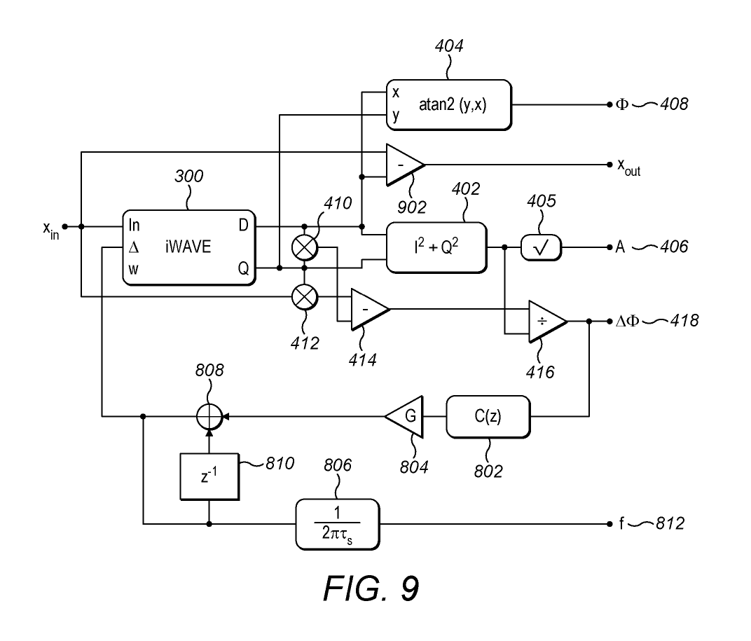

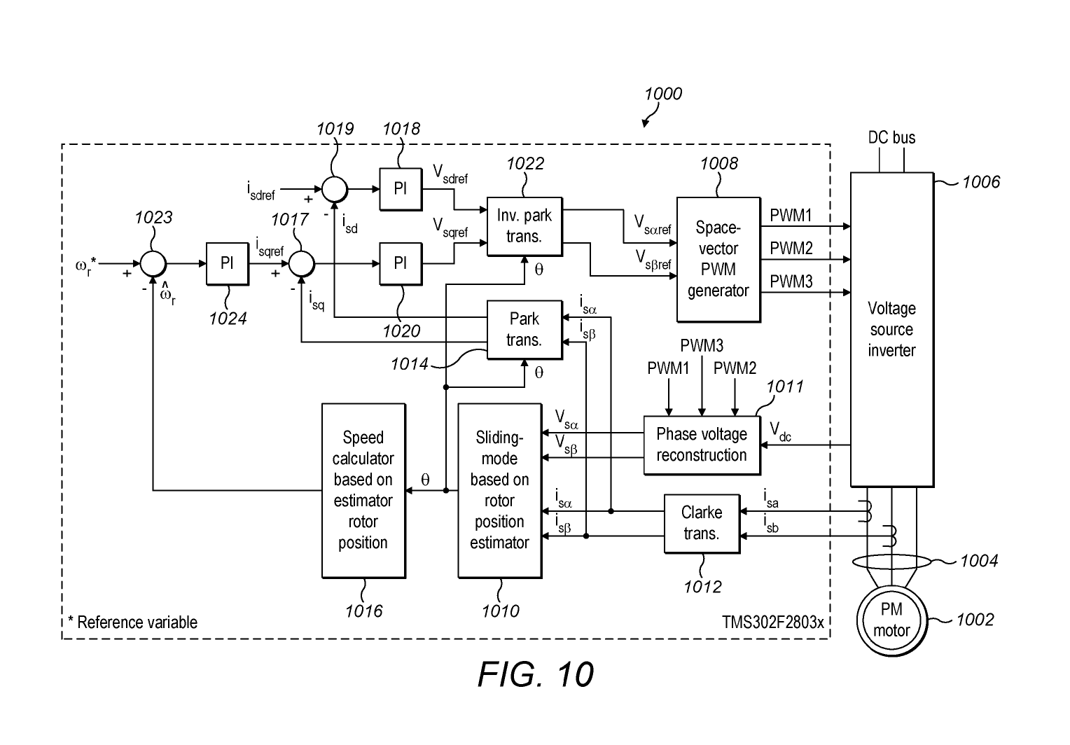

As set out above, the iWAVE based systems illustrated in FIGS. 3 to 8 may be used to characterise and track oscillations with both fixed and variable frequency and phases. Furthermore, the D phase output of iWAVE has a phase, a frequency and an amplitude corresponding to the average behaviour of the oscillation being tracked in the input signal waveform. Consequently, the D phase output may be used to cancel signals from an input signal waveform in which multiple oscillating components may be present. FIG. 9 provides an illustration of such an iWAVE implementation.

The operation of the system in FIG. 9 is substantially similar to that of the phase-locked loop of FIG. 8 and therefore will not be described in detail. However, it includes a further subtraction unit 902 which is arranged to subtract the D phase output from the current input signal to provide an output signal xₒᵤₜ in which the oscillation being tracked has been substantially removed. More specifically, since the D phase output has an amplitude, phase and frequency approximately equal to the oscillation being tracked, by subtracting the D phase output from the input signal waveform, the oscillation being tracked is substantially removed from the input signal waveform.

The use of the system of FIG. 9 for the cancellation of signals may be used in a wide range of scenarios where a signal of interest is hidden by an interfering signal or signals. For example, in a communications system an interfering waveform may be removed from a received signal thus enabling the signal of interest to be identified and demodulated more reliably. Likewise, as is described in more detail below, a drive signal of an electric motor may be cancelled from a current measured on a drive coil of an electric motor, thus allowing other signals such as current corresponding to a back electromotive force to be detected and analysed.

The iWAVE implementations set out above are illustrative examples only and the algorithm steps represent by the iWAVE element 300 and set out in FIG. 2 may be used in any scenario where an oscillating component, preferably sinusoidal, is required to be characterised, tracked or generated. Although, the input signal waveform has been described as including a sinusoidal oscillating component, it may also contain noise such additive white Gaussian noise, coloured noise or noise resulting from signals such as co-channel interference in communications system.

The ability of iWAVE to provide outputs D and Q phase which represent or provide an indication of the average phase, amplitude and frequency of an oscillating component of a input signal enables noise in the input signal to be rejected as an increased level compared to existing wave characterisation method such as the Fourier transform for instance since iWAVE does not simply characterise a wave based on two adjacent samples a number of samples determined by w.

Up to this point, real inputs to iWAVE have been predominantly considered. However, iWAVE may also be applied to imaginary input data, such that the iteration equation (3) is applied to imaginary input data. Examples of such input data may include signals containing two substantially orthogonal phases representing the first oscillating component. For instance, where a signal frequency is relatively high, two transducers may be positioned on the line carrying the signal in positions so that the transducer outputs are x1(n)=cos nΔ and x2(n)=sin nΔ. In another example, it is common in the reception of high frequency RF and microwave signals for the signals to be demodulated in two orthogonal phases by mixers, such that the outputs of these mixers contain a pair of orthogonal signals. Regardless of how the signals with orthogonal phases arise or are generated, the two signals can be made into the imaginary superposition using the following relationship x(n)=x1(n)+jx2(n)=cos nΔ+j sin nΔ=e^{jnΔ}. Referring to equation (3) in a form where the input xₙ has been scaled by a real constant as follows:

yₙ=(1−e^{-w})xₙ+e^{jΔ-w}yₙ₋₁.

Given that equation (3) is linear, this scaling of the input only results in the scaling of the output by the same factor, and does not otherwise alter the Z-transform estimate formed by the recursion relation based on Δ and w. The imaginary input x(n)=x1(n)+jx2(n)=cos nΔ+j sin nΔ=e^{jnΔ} is an eigenfunction of this iteration operator having eigenvalue +1, so that, crucially, the output yₙ follows the same circular locus as the inputs xₙ. Consequently, for this particular choice of input data, no matrix transformation is needed to yield the action-angle variable representation of the input data as was the case for xₙ real since it is not necessary to map an elliptical locus onto a circular locus. Therefore the frequency and phase of the oscillation of interest can be estimated directly from yₙ and the D and Q phase outputs can be formed directly from yₙ. Thus the iWAVE method in the case of two input data samples containing oscillating components out-of-phase with each other in this way is computationally simpler than the case of a real oscillating input. We call this simpler complex implementation ‘icWAVE’, where the c indicates that two input signals are combined to form the real and imaginary parts of a complex input to the iWAVE algorithm. The particular choice of the scaling of the input yields the iWAVE output in-phase with the input having the same amplitude as the input, although the output is effectively averaged over a lookback time corresponding to w such that the SNR of the oscillation of interest represented by the output signals has been increased compared to the input signals.

Although the icWAVE implementation is computationally simpler due to the absence of the matrix transformation, the iWAVE and icWAVE share the performance characteristics set out above and below, and also the characteristics of the Q and D phase that are output. Consequently, the processing that may be performed on the Q and D phases is similar and thus the applications of the two implementations is similar. For example, the implementations based upon iWAVE set out below are equally applicable to icWAVE although the icWAVE requires the oscillation of interest to be represented by two out of phase input waveforms that can be combined to form a complex representation of the oscillation of interest.

### Control Applications

Although up to this point iWAVE have been described with reference to the characterisation of an oscillation, parameter estimation, and tracking of an oscillation, iWAVE may also be used as part of a control apparatus that utilises one or more of these functions of iWAVE. For example, iWAVE may be used to extract information from signals associated with some form of plant, and the extracted information analysed and utilised to control the plant via the provision feedback based upon the extracted information. The plant may take any form but preferably the information to be extracted should be in the form of a sinusoidal type signal which iWAVE is adapted to operate with. For instance, iWAVE may be used to monitor the rotation of a physical object such as a wheel where the displacement of a point of the circumference of the wheel from a reference point may be represented by a sinusoid signal. Alternatively, in the case of jamming radio communications, the phase-lock loop implementation described above may be used to track a carrier signal, and one or more of the frequency, phase and amplitude of the carrier signal output from iWAVE may be used to control the transmitter to transmit a jamming signal at the same frequency and phase as the carrier signal. For example the D phase output may be amplified and transmitted as the jamming signal.

As set out above, the iWAVE algorithm is based upon the presumption that the signals to be analysed are sinusoidal. Since sinusoids have a predictable behaviour, iWAVE is operable to output a phase difference which represents the difference in expected phase (i.e. average phase) and actual phase of the input signal. Consequently, if the phase of the input signal changes, this change can be detected by a homodyne or an equivalent detector operating on the output of iWAVE. Advantageously, this arrangement enables iWAVE to monitor the phase of a signal with only one input and thus measuring only one point on the input signal waveform. In turn this enables the use of only one sensor to measure the phase of a signal. As a consequence of this, control apparatus based on iWAVE and their implementation may be simplified and thus their cost reduced compared to conventional control apparatus, as well as increased reliability due to the use of fewer sensors. As will be discussed in more detail below, the requirement of only a single measurement point or sensor allows control apparatus based upon iWAVE to be retrofitted to existing systems with reduced cost and complexity compared to existing sensor arrangements that may be retrofitted.

### Motor Control

Although iWAVE based techniques may be utilised in a wide range of applications, its application to control of both synchronous and asynchronous presents a number of advantages due to, among other things, the sinusoidal nature of drive signals and the minimum requirement of a single sensor for monitoring the phase of the motor. The application of iWAVE to motor control is described in more detail below with reference to the control of synchronous and asynchronous motor control.

Electric motors are formed from a rotor and a stator which rotate relative to each other when a voltage is applied across a drive coil to induce a current in the drive coil. In the case of synchronous motors such as permanent magnet motors, a drive voltage and thus a drive current are applied to drive coils in the stator surrounding the permanent magnets of the rotor. The magnetic field generated by the drive current interacts with the magnetic field arising from the permanent magnets located on the rotor and thus causes the rotor to rotate. As an alternative to permanent magnets, electromagnets which are provided with a current separate to the drive current may also be used. Synchronous motors may operate with both alternating current (AC) and DC, however, the defining characteristic of synchronous motors is that the frequency of the drive signal is an integral multiple of the frequency of rotation of the rotor, the multiple being the number of north poles of the permanent magnet assembly.

In the case of asynchronous motors, such as induction motors, as opposed to permanent magnets or electromagnets, the magnetic field generated by the drive current induces a corresponding current in the windings on the rotor which in turn generates a magnet field that interacts with the magnetic field generated by the drive current to cause the rotor to rotate. These windings of the rotor may be referred to as a squirrel cage due to their resemblance to a rodent exercise wheel. As for synchronous motors, the drive current may be applied to either the stator or the rotor. However, in order to reduce the use of communicators, the drive current is conventionally be applied to the stator. The term asynchronous refers to the fact that the rotation frequency of the drive is not an integer multiple of the rotation frequency of the rotor as is the case for synchronous motors. In particular, in asynchronous motors there is an accumulation of phase because the drive frequency is larger than some integer multiple of the rotation frequency is referred to as slip.

To control electric motors the parameters of the drive voltage and therefore drive current are controlled. In particular, the frequency of the drive current is used to control the frequency of rotation of the rotor, the amplitude of the drive current is used to control the torque applied to the rotor, and the phase may be controlled to help ensure that the torque provide by the drive current is applied at the correct point of rotation of the rotor so that the force exerted on the rotor is substantially parallel to the direction of rotation of the rotor. Although drive currents have been described as a single current, often a plurality of drive currents will be present in a plurality of drives coils, where the separate drive coils may each have separate drive current which is out of phase by a predetermined amount with the other drive currents. For example, if a motor has three drive coils, the current in each coil may be out of phase by 120 degrees from one another.

### Synchronous Motor Control

Synchronous motors such as permanent magnet brushless direct-current DC motors are conventionally controlled via a control scheme referred to as vector control, which is illustrated in FIG. 10. At its core, the control scheme relies on inferring the position of the rotor from the drive current that flows through the drive coils of the motor and the current corresponding to the back-EMF which has been induced in the drive coil by the rotating magnetic field generated by the permanent magnets of the rotor. In particular, when a magnet pole reaches its point of closest approach to a drive coil, the rate of change of flux through the coil is zero, and hence the back-EMF in the drive coil has a zero value. A maximum back-EMF signifies a maximum rate of change of flux, occurring when the coil is equidistant between opposite magnet poles. Consequently, the phase of the back-EMF tells you where the magnet poles are relative to the drive coils. However, a number of stages are necessary to extract such a position estimate and control the applied voltage accordingly.

A vector control scheme is based upon on a representation of a motor state in a rotating frame of reference. The frame is arranged to rotate based on a reconstructed rotor angle θ. In the vector control apparatus 1000 of FIG. 10, which is based on the Texas Instruments TMS302f2803x motor controller, the reconstructed rotor angle of the permanent magnet motor 1002 may be derived from six signals: two measured currents (iₛₐ and i_{sb}) from two out of the three coil drives 1004, a single D.C. voltage (V_{dc}) from the inverter stage 1006, and the three voltages (PWM1, PMW2, PMW3) from the output of the pulse width modulation generator 1008 that drives the inverter stage.

The rotor angle is derived using an algorithm known as a sliding mode position estimator represented by sliding mode position estimator 1010, where the voltage outputs from the pulse width modulation generator and the inverter stage are passed through a phase voltage reconstruction unit 1011 prior to input into the estimator 1010. As well as being used as inputs to the sliding mode position estimator 1010, the two measured currents, which are nominally sinusoids at the motor rotation rate, but out-of-phase with each other by 120° because of the phase difference between the three pairs of windings, are passed through a Clarke transform 1012, which converts sinusoids at 120° phase mismatch into sinusoids with a 90° phase mismatch. One of these transformed signals is then in-phase with a coil current. As mentioned above, the currents sensed in the drive coil include a current corresponding to the back-EMF induced by rotation of the rotor and the magnets thereon. Therefore with knowledge of the drive voltages, and the sensed drive coil currents, the back-EMF, and thus the rotor angle θ, can be inferred.

These Clarke transformed coil current signals, along with the reconstructed rotor angle from the sliding mode estimator 1010, are fed to a Park transform 1014, which calculates the D-phase and Q-phase components of the current in the synchronous reference frame where the rotor is stationary. The D-phase current corresponds to the component of the stator current that increases/decreases the strength of the magnetic field in the air gap between the rotor and stator, whereas, the Q-phase current provides the torque needed to increase/decrease the rotational speed of the rotor. The speed of the rotor may then be calculated from the rate of phase increase i.e. rotor position, by a speed calculation unit 1016.

If the coil currents are sinusoids whose phase is increasing at the same rate as the sliding mode position estimator, then the point position representing the phase of the coil currents in the rotating frame remains fixed. If the rotor starts to slow down, then the point will rotate about the origin in the rotating frame one way, since the sliding mode position estimator will start to lag the rate of increase of the phase of the coil currents; if the rotor starts to speed up, then the point will rotate in the other direction. The error signal for torque control is the departure of this point in the rotating frame from a fixed quiescent value and is calculated by substation units 1017 and 1019. This error signal is fed through Proportional-Integral-Derivative (PID) controllers 1018 1020 and an inverse park transform 1022 to drive the generator 1008 for the coil signals. Increased torque is applied if the rotor rotation rate starts to lag the phase increase rate in the applied drive, and vice versa. In addition, the rate of change of θ is used to deduce the rotor speed by the speed calculation unit 1016. This speed is compared to a set point by subtraction unit 1023, and the difference feeds a PID controller 1024 whose output adds to the applied torque. By this mechanism, speed control of the rotor is achieved.

Although the vector control scheme described above with reference to FIG. 10 is widely utilised, there are a number of disadvantages to its use. Firstly, two coil currents are required to be measured, amplified differentially and digitised to run the sliding mode position estimator, thus at least two sensors are required. Secondly, the sliding mode position estimator models the drive currents and DC inverter voltage simply as single samples derived from single samples, and the rates of change of drive currents as differences between neighbouring pairs of values. Consequently, these methods estimate derivatives by the difference between successive data samples and thus have a reduced accuracy since single sample measurements are more susceptible to noise than aggregates over many samples. Thirdly, the vector control method does not make use of the inherent sinusoidal nature of the voltages and currents in the drive circuit since it simply utilises adjacent samples of the drive currents and coil currents.

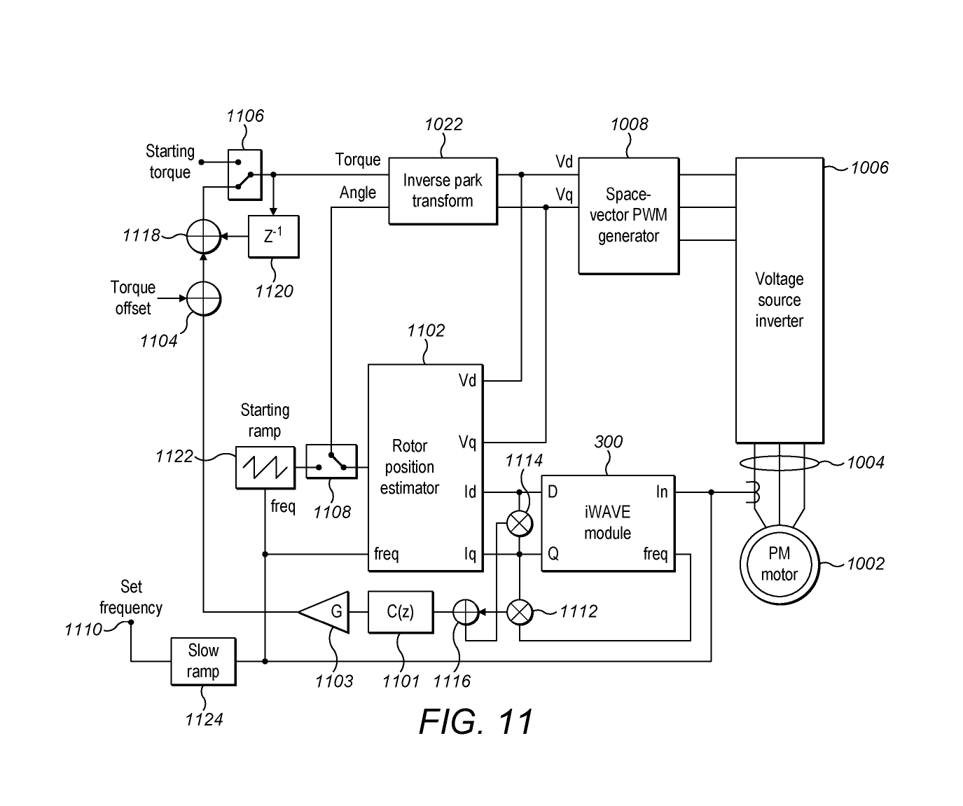

The use of an iWAVE based motor controller may address one or more of these disadvantages since an iWAVE controller may estimate the rotor position with one sensed current rather than at least two. Furthermore, since iWAVE reflects an average behaviour of an oscillation (back-EMF) over the response time and takes advantage of the sinusoidal nature of the voltage and drive currents, improved rejection of noise may be obtained. FIG. 11 provides a diagram of an iWAVE based synchronous motor controller in accordance with an example of the present invention.

FIG. 11 is a schematic of an iWAVE based synchronous motor controller in accordance with an example of the present invention. As set out above, in iWAVE all signals (applied voltages and sensed currents in terms of motor control) are modelled as sinusoids. Since sinusoids have a known functional form over many samples, the iWAVE algorithm naturally provides a mechanism for the rejection of noise due to the response time which acts to provide average characteristics of the sinusoids. Furthermore, the iWAVE algorithm produces in-phase (D) and out-of-phase (Q) sinusoids relative to the coil current, so only one coil current signal is required rather than two or more as in conventional vector motor controllers.

A single sensed current is input into the iWAVE module 300, where the sensed current is the current in one of the driving coils in the synchronous motor 1002. The D and Q phase outputs of iWAVE are fed to an angle estimator 1102, which is discussed in detail below. The angle from this estimator is fed directly to the inverse park transform that acts as a secondary oscillator generating signals to be applied to the coils through the same chain of components (inverse Park transform 1022, space-vector PWM generator 1008, voltage source inverter 1006) as employed in the vector control method of FIG. 10.

The configuration of iWAVE in FIG. 11 is analogous to the WAVE oscillator illustrated in FIG. 7. The resonant character of iWAVE is used in a closed loop feedback configuration incorporating the plant (in this case the motor), feedback filter 1101 and gain block 1103 which satisfy the Nyquist criterion thereby ensuring a stable sine-wave oscillation around the loop, which thereby helps ensure that the motor continues to oscillate at the rate set by the Δ input to iWAVE. The motor speed is controlled by adjusting Δ using the input 1110.

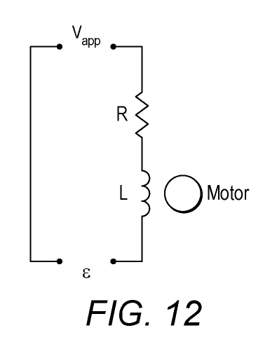

The rotor position estimator 1102 provides an estimate of the rotor position relative to a reference point in the motor. As set out above, the position of the rotor can be inferred from the back-EMF induced in the drive coil as a result of the rotation of the magnet coupled to the rotor. More specifically, FIG. 12 illustrates an equivalent circuit for the drive coil of an electric motor. In FIG. 12, Vₐₚₚ represents the drive voltage, R and L represent the resistance and inductance of the motor respectively, and ε represents the back-EMF generated by rotation of the rotor. The circuit of FIG. 12 may be described using the following differential equation where is the current flowing in the circuit.

$${V}_{app} - Ri - L \frac{di}{dt} = ɛ . \qquad ( 16 )$$

If each signal of Eq. 16 is modelled as a phasor with an angular frequency of ω, an estimate of the back-EMF ε may be obtained according to the following equation

\tilde{ε}= [symbol] −Rĩ−jωLĩ. (17)

The quantities on the right of Eq. 17 are available from the outputs either of iWAVE or of the direct readouts of the applied voltages from the inverse Park transform. The applied voltage can be read out from the park transform, the current in the resistive term can be read out from the D phase iWAVE output, and the current in the inductive term phase shifted by 90° as indicated by the j in the phasor equation is the Q phase iWAVE output. Thus knowing the values of R and L, the back-EMF can be inferred, assuming sinusoidal behaviour, which when the motor is under control it is expected to be the case. The advantage of this method over the difference equation approach of the conventional sliding mode controller is that averaging over several cycles of a sine wave provided by iWAVE leads to an increase in the signal to noise ratio in the measurement of the rotor position, and only one sensed current is required.

Once the rotor position information has been extracted from the sensed current, and the current associated with the back-EMF in particular, the control system operates such that the drive voltage is in phase with this signal. This therefore beneficially reduces the likelihood of exerting force towards the coil at the point where the pole reaches its closest approach since such forces will tend to push or pull the magnet pole rather than exert a torque.

Depending on the load placed upon the motor, the application of varying levels of torque may be required in order to ensure that the rotor rotates at the desired frequency. These differing levels of torque are applied by varying the voltage and therefore current applied to the drive coils.

When the torque applied to the motor is greater than that required to cause the rotor to rotate at the set frequency, the rotor will accelerate between drive coils, arriving early at the next coil compared to its arrival time if a constant rotation rate in assumed. In arriving early, the magnet pole generates back-EMF that leads the sine wave output by iWAVE. This phase lead is detected using the homodyne detection scheme described above and illustrated by addition unit 1116 and multiplication units 1112 and 1114. The output of the homodyne detector is fed back through a servo filter 1101 and gain unit 1103 to control the amplitude of the sinusoids applied to the drive coils, and hence the torque by adding the desired change in torque to the current torque value using adder which includes the previous torque value from the unit delay block, 1120.

If the rotor torque is insufficient to match the set rotor velocity, then the rotor will tend to arrive later at the next coil compared to the arrival time assuming a constant rotation rate, resulting in a phase lag, which produces a homodyne detector output having the other sign, and the torque is consequently increased. Finally, for stability purposes it may be desirable to run with torque in excess of the minimum required. In this case a controlled torque excess can be added in the feedback path, as shown by the adder 1104.

To begin rotation of the rotor a starting torque and frequency signal is required. In FIG. 11 this is achieved by initially switching in a starting torque via switch 1106 and switching in an angle signal based upon the desired frequency and a ramp unit 1122 via switch 1108, where the desired frequency is set via input 1110. In order to ensure a stable motor rotation when the motor is started or its frequency changed, the frequency input at 1110 maybe passed through a ramp unit 1124 the frequency of the motor is increased gradually to the desired frequency.

### Asynchronous Motor Control

In contrast to synchronous motors, in asynchronous motors the drive current and the rotation of the rotor are not in phase. Thus, the currents induced in the drive coils as a consequence of the rotation of the squirrel cage will have a different frequency than the currents resulting from the drive. Furthermore, the frequency of the squirrel cage-induced currents will vary with the torque on the motor between the theoretical limit of zero torque and some maximum operating torque, where the greater the torque, the greater the slip, and the lower the frequency of the rotor. Above the maximum operating torque, further increases in torque results in a decrease in the rotation rate, so the motor ceases to rotate.

iWAVE provides a technique to measure the frequency of rotation of the rotor without recourse to an independent position or rotation rate sensors. This is done by sensing the current in a single drive coil and passing this current through an instance of iWAVE with the frequency set to the frequency of the applied drive signal. The D phase output of iWAVE represent the drive current and is then subtracted from the input rotor current to remove the drive current sinusoid from the drive coil current. The residual signal, which contains the back-EMF, noise and possible further harmonics related to rotation of the rotors, is input into a second iWAVE unit, where this iWAVE unit operates in phase-locked loop mode, as described with reference to FIGS. 8 and 9. Further sinusoids in the drive coils due, for example, to residual mains frequency oscillations and their imprint on the charge/discharge cycle of capacitors used to store electrical charge to be switched in to the motor coils, can be subtracted from the measured coil current signals by further instances of iWAVE. Presuming the input signal to the second iWAVE unit is dominated by the induced back-EMF from the rotor rotation, iWAVE tracks this frequency, and adjusts its phase shift per sample to track it as it changes. This frequency then corresponds to the speed of rotation of the rotor, and can be used to control the motor speed accordingly.

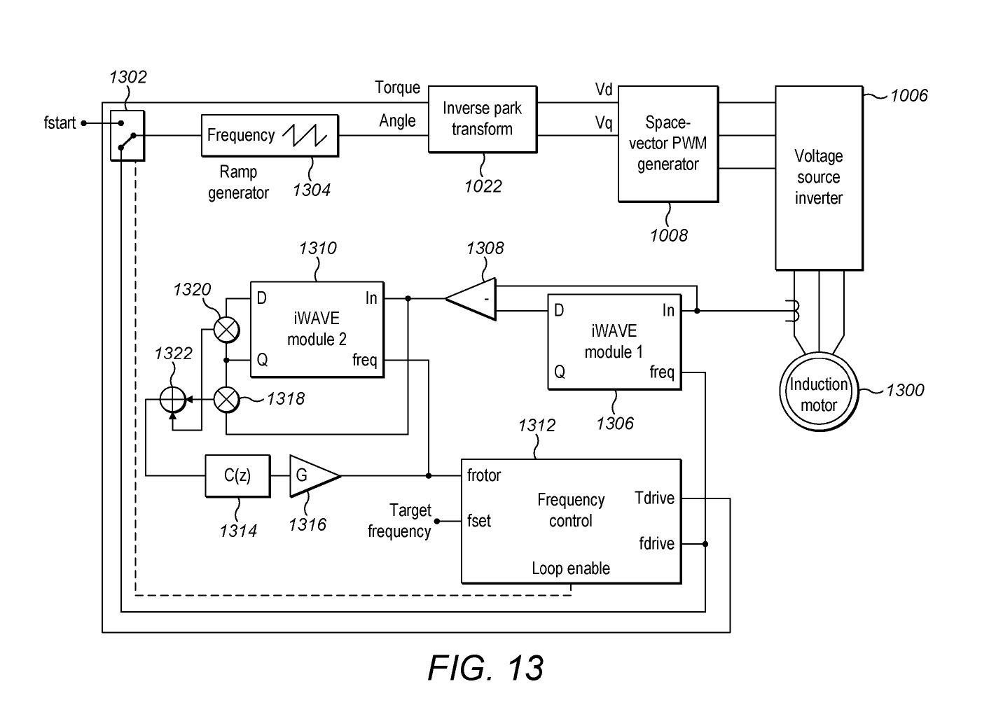

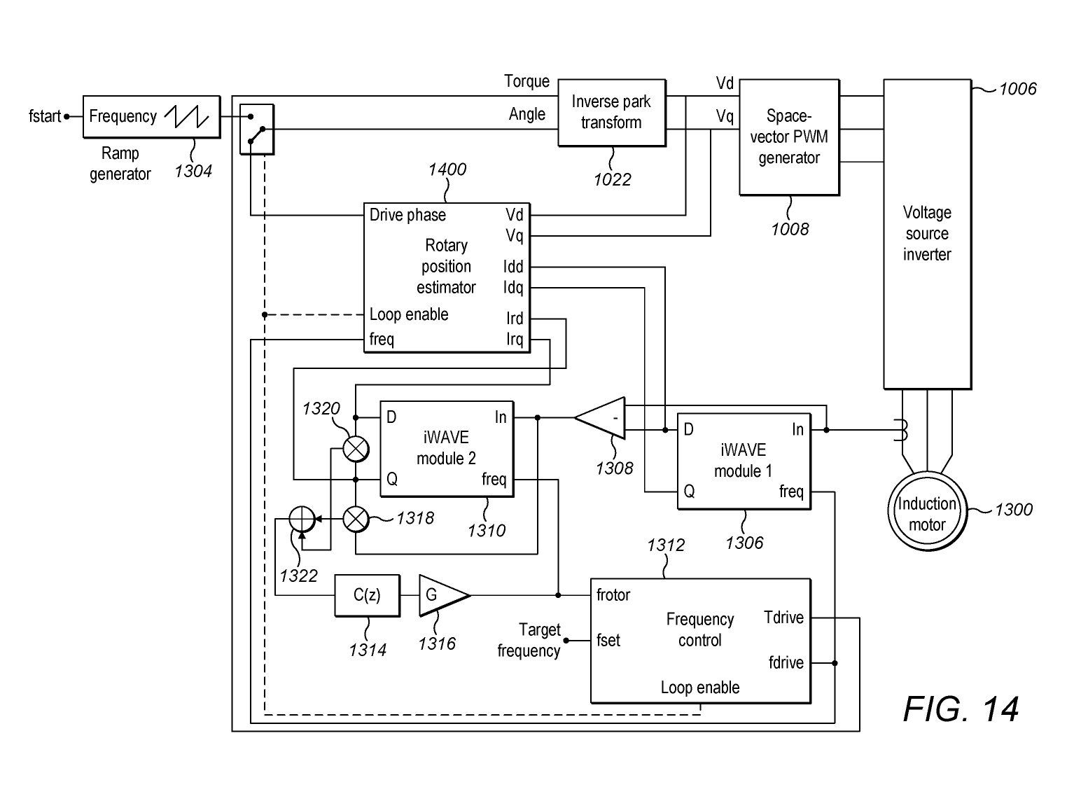

FIG. 13 provides a schematic diagram of an induction motor control technique in accordance with an example of the present invention. The starting mode includes the application of a fixed frequency drive to the motor 1300 via switch 1302 which in turn supplies the fixed frequency drive to a ramp generator 1304. The signal generated by the ramp generator 1304 provides an angle signal to the inverse park transform 1022, which in turns provides voltage signals vd and vq to the pulse width modulator generator 1008 and the voltage source inverter 1006 which drives the motor.

The first iWAVE unit 1306 in configured to track the drive current, where in an initial state the input frequency is the present drive frequency. In this initial state, the measured coil current will be dominated by a sine wave at the drive frequency and thus the iWAVE outputs will reflect the average behaviour of drive current. The in-phase output from iWAVE 1396 is then subtracted from the measured signal by subtracting unit 1308 resulting in a signal which is predominantly made up of noise at initial start-up. As the rotor starts to rotate, a second signal will appear as the back-EMF becomes significant due to the increased rate of change of flux through the drive coils. The second iWAVE controller initially sees broadband noise and transients, but as the rotor speed increases a sinusoidal signal at the rotor frequency will emerge. This signal sweeps up in frequency as the rotor speeds up. The second iWAVE 1310 may have an initial set frequency which is intermediate between zero and the drive frequency for example. Subsequently, when the rotor frequency becomes sufficiently close to the initial frequency, the phase-locked loop of iWAVE 1310 formed from the feedback filter 1314, gain unit 1316 and adders and multipliers 1318 1320 1322 closes and locks to the signal representing the rotor frequency. The frequency control input of iWAVE 11310 then represents the rotor frequency (frotor). This second frequency (frotor) is read out by a frequency controller 1312 along with a target frequency (fset), where the frequency controller 1312 also has knowledge of the current drive frequency (fdrive). The drive frequency is then controlled until the rotor frequency equals the set frequency. The torque (Tdrive) is determined by the drive current necessary to make the rotor run at the target frequency. Therefore, the amplitude of the drive current may be increased if more torque is needed to achieve the target frequency with a given load and vice versa. The amplitude of the drive current applied to the motor is thus also input to the frequency controller.

In addition to controlling the frequency of the drive signal, the phase of the drive signal relative to the rotor position may also be controlled. In particular, since at the limit of low torque the rotor rotation rate may be approximately equal to the drive frequency, the phase can be determined with good accuracy using the same angle position estimator scheme as described with reference to FIG. 11. However, with higher torques, the rotor frequency is lower than the drive frequency, so it becomes more difficult to match the timing of the drive sinusoid to the rotor position relative to the drive coils.

Consequently, to match the phase, information on both the applied voltage/current at the drive frequency and also the current at the rotor rotation frequency may be required. FIG. 14 shows a simultaneous control scheme for the frequency and the phase of the applied drive signal relative to the rotor position which has information to optimise the phase of the drive signal at motor torques where there is a significant difference between the drive frequency and the rotor frequency. Compared to FIG. 13, the controller architecture of FIG. 14 includes a rotary position estimator 1400 for the rotor based on the D and Q phases of the applied voltage and the current components at the drive and rotor frequencies as determined from the two iWAVE module outputs. The frequency of the drive signal is an additional input. There is also a loop enable that allows the estimator to activate based on the frequency of the rotor, and a ramp that is used as input for the inverse park transform prior to operation of the rotary position estimator.

The overall structure of an iWAVE based motor controller in FIGS. 13 and 14 may also have a number of parameters that may be tuned according to the current state of the motor. For example, it may be advantageous to varying the response time of iWAVE dependent on the rotational speed of the motor rather than utilise a fixed response time. In particular, in order to allow the controller to effectively control the motor at low speeds, it may be beneficial to increase the response time so that the behaviour of the motor is averaged over a sufficient number of cycles to achieve useful noise reduction at low speeds.

The use of the motor controllers of FIGS. 13 and 14 allow induction motors to be controlled with only one current sensor and also for them to be effectively controlled at low speeds. This is contrast to many existing approaches to induction motor control which require multiple current sensors or physical rotational sensors, and may only begin controlling the motor when it has achieved a minimum speed. Furthermore, since the sensors of an induction motor are susceptible to failure, reducing the number of sensors via the use of the iWAVE controller may also lead to improvements in reliability. Motor efficiency may also be improved through the use of an iWAVE based control scheme since the iWAVE controller can operate at substantially all motor speeds and ensure the driving currents are, as far are possible, in phase with the rotational of the rotor. Lastly, induction motors are often run at very low torques via the use of a gear box in order to minimise slippage and the associated efficiency losses due to the slip between the drive frequency and an integral multiple of the rotation rate of the motor. However, iWAVE based controllers may reduce the need for gear boxes since it allows induction motors to run more efficiently at higher speeds and higher torques due to the ability to accurately and quickly measure rotor position and adapt the drive currents accordingly.

The approaches to wave characterisation, parameter measurement and apparatus control described above may be implemented using any appropriate means. For example, they may be implemented in hardware, software or a combination of the two. When implemented in software, computer readable instructions or code embodying the above described techniques may be stored on a computer readable medium or transmitted over a communications network. These instructions when executed on a computer cause the computer to perform the above described techniques. Some or all of the above methods may also be implemented in programmable logic as opposed to on a computer, for example, on a Field Programmable Gate Array, or other special-purpose logic configuration. Or, the above methods may be implemented in a computer connected to programmable logic, with the programmable logic performing and the computer sharing implementation of the above described techniques.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

### Cantilever Measurements for Atomic Force Microscopy

Atomic Force Microscopy (AFM) is the probing of a sample using a fine tip mounted on the end of a cantilever. Vibrations are induced in the cantilever, and the motion of the tip/probe is monitored as the vibrating tip is brought into proximity with the sample being studied. As the tip approaches the surface, the electrostatic potential of the surface modifies the motion of the cantilever from its free space behaviour. The amplitude of the vibration is a function of the tip position such that when the cantilever is driven at a fixed frequency, the actual frequency of the cantilever includes a transient oscillatory component not at the drive frequency for a time of order the damping time of the cantilever mechanism in free oscillation when the tip displacement from the surface is altered, thus providing information on the position of the tip. Subsequently, by measuring this oscillatory component(s) of the vibrations, information on the position of the tip and thus information on the sample being studied obtained.

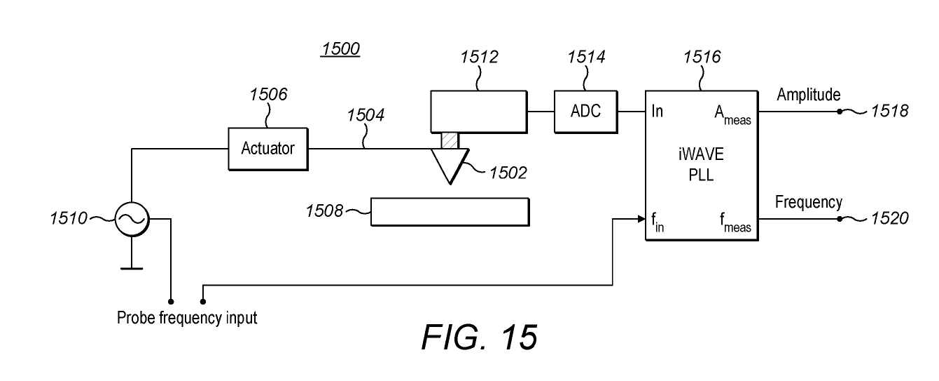

Given the ability of iWAVE to extract the phase and frequency of oscillating components in a signal, and also track the signal when in a PLL arrangement, iWAVE is suitable to be applied to readout of an atomic force microscope probe, which is illustrated in FIG. 15. The iWAVE filter is capable of measuring small changes in the amplitude and the frequency of the cantilever motion, with advantages over the more conventional lock-in amplifier technology used for this task in terms of economy, since iWAVE may be implemented on low cost programmable logic and computer hardware. Furthermore, as outlined earlier, the iWAVE PLL as described with reference to FIG. 8, has increased robustness robust as the only tuneable degree of freedom is frequency, which in this case does not depart substantially from the drive frequency.

In FIG. 15, a probe/tip 1502 of the atomic force microscope 1500 is attached to a cantilever 1504 which is driven by an actuator 1506 such that the probe 1502 vibrates as the sample 1508 under study is scanned. The actuator 1506 is itself driven by an oscillator 1510 operating at a probe drive frequency. As set out above, the actual movement of the probe 1502 differs to that of the drive frequency due to the interaction of the probe with the sample 1508, and thus a transducer 1512 outputs an electrical signal representing the movement of the probe 1502, which includes information of the oscillation(s) resulting from interaction with the sample 1508. The electrical signal is sampled by the ADC 1514 and then input into an iWAVE PLL 1516, which is similar to that of FIG. 8. Using the iWAVE PLL, the frequency and amplitude of the vibrations of the probe can be tracked and measured and thus information on the sample 1508 obtained using the outputs 1518 and 1520. The iWAVE PLL 1516 is configured to operate initially at a frequency (fin) corresponding to the probe drive frequency since the resulting movement of the probe 1502 would not be expected to differ significantly from the probe drive frequency.

### Electricity Generation

The injection of electricity from a generation facility, for example a solar farm or a wind turbine array, into a mains power grid requires dynamic determination of the local mains voltage and current. Such measurements may also be required in scenarios where the measurement of voltages and current for the calculation of power are performed. iWAVE therefore once again therefore provides an efficient an accurate approach for the determination of such parameters.

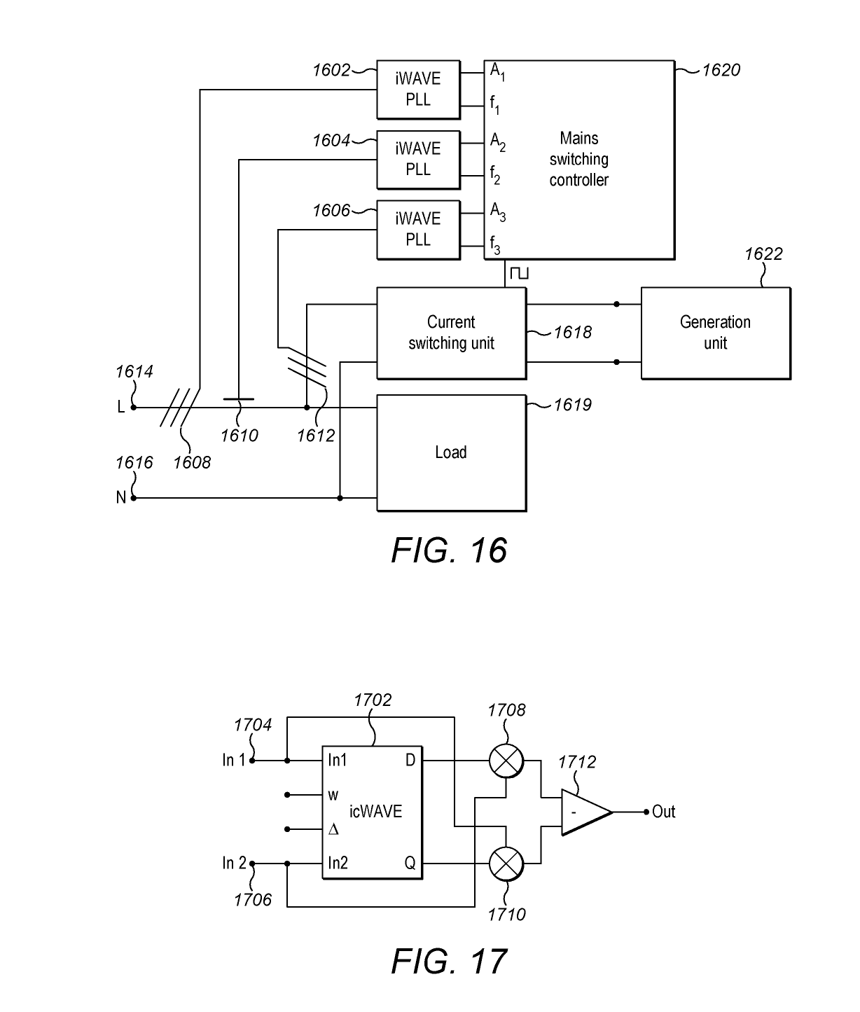

FIG. 16 provides an illustration of the application of iWAVE to sensing of voltage and current in mains wires in an electrical power generation facility. iWAVE PLLs 1602, 1604, 1606 are connected to transducers 1608, 1610, 1612 that provide signals representing the current and voltage at the point of entry of the mains 1614 1616 into the facility, as well as the current in the wires connecting the current switching unit 1618 system to the mains and any loads 1619 connected to the mains. The dynamic determination of the amplitude and frequency of each of the sensed signals is carried out by iWAVE PLLs 1602, 1604, 1606. The amplitude and frequency outputs from the iWAVE PLLs are used as inputs to a mains switching controller 1620 that controls the current switching unit 1608 connecting the generation unit 1622 to the mains power grid/network and thus the injection of power into the grid.

One of the advantageous characteristics of iWAVE in this scenario is that the bandwidth of the iWAVE filter may be set by adjusting w to reject noise in the mains voltage and current, therefore isolating the switching power supply from mains transients which may otherwise lead to undesirable transient injections of local generated power onto the grid.

### Decoding of Phase Shift Keying Signals for Communications.

Receiver circuits for mobile phones and other radio receivers are required to measure phase shifts in the carrier wave when receiving and demodulating signals that have been modulated using technique based upon phase shift keying. Consequently, the iWAVE algorithm, and more precisely, the icWAVE algorithm can be used for efficient decoding of phase shift keyed signals.

Conventional receivers first separate the carrier signal into two orthogonal phases which may represent the real and imaginary elements of the received complex signal for example. Subsequently, these signals can be passed through the icWAVE filter to recover phase shifts and thus demodulate the signals and recover the transmitted data.

FIG. 17 provides an example implementation of the icWAVE for receiving phase shift keying modulated signals. The icWAVE frequency ∇=f/(2πτₛ) is set equal to the intermediate frequency (IF), which is the difference between the RF carrier frequency and the local oscillator frequency that is used to down convert the received signal. The two input signals 1704, 1706 are input to the icWAVE but also multiplied by the output D and Q output phases respectively using the multipliers 1708, 1710. The phase shift sensitive output is the difference between the product of the in1 input 1704 with the Q phase output and the product of the in2 input 1706 with the D phase output. This combination suppresses the down converter output component at twice the IF frequency without the use of a bandpass filter. We show this by considering a complex input signal as consisting of a sinusoidal oscillation in two phases plus a phase discontinuity, so that the input to icWAVE can be written as a complex number, xₙ=cos(ωt+φ)+j sin(ωt+φ), where φ is the phase disturbance. The inputs are multiplied by the D and Q phase icWAVE outputs as illustrated in FIG. 17, and the difference between the resulting product terms is taken, yielding the output yₙ=sin φ(cos² ωt+sin² ωt)+cos φ(cos ωt sin ωt−sin ωt cos ωt)≈φ, where the final step is taken in the limit of small φ, which will be true when the phase departures are less frequent than the iWAVE averaging timescale, τₛ/w. Note that there is no component at twice the wave frequency because these components are converted to DC (low frequency) by the action of trigonometric identities equivalent to the operations illustrated by FIG. 17. The residual DC offset component is thus present when the phase of the carrier wave shifts, thus providing a measure of the phase shift, and thus allowing demodulation of the transmitted data.

As set out above, icWAVE algorithm is sufficiently simple, due to the absence of the matrix transformation, that the entire decoding apparatus can be implemented in hardware such as programmable logic for example. Consequently, the speed and power consumption of demodulation are increased and reduced respectively, compared to software implemented demodulation. Furthermore, the adjustable parameter w of the icWAVE algorithm can be set to optimise bandwidth of the filter to match the bandwidth of each mobile communication channel, and/or adjusted to change the response time and lookback time of icWAVE. In turn this allows the icWAVE to be adjusted to take account of varying channel conditions and modulation schemes. Additionally, in comparison to the conventional approach of demodulating using trigonometric techniques, iWAVE result in improved bit error rates (BER) at a receiver, since, due to the effective averaging which takes places in iWAVE/icWAVE, noise and/or interference is suppressed and the SNR/SINR of signals effectively increased. In turn, this may also allow the use of higher order modulation schemes, which require a higher SNR to operate correctly, thus increasing potential data rates of phase shift keying based communication systems.

icWAVE Motor Control

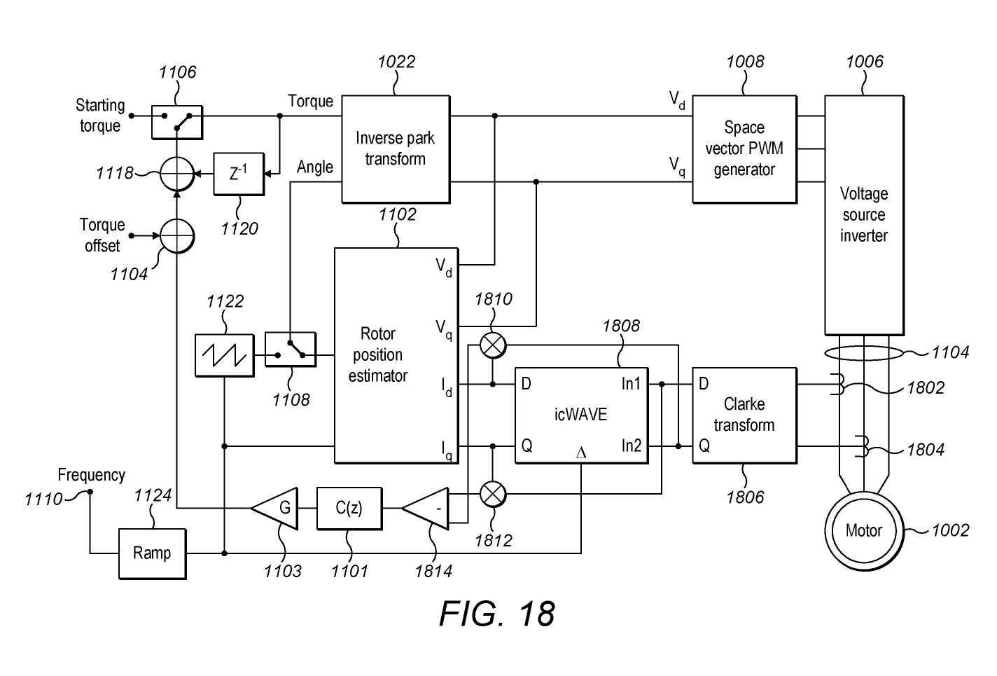

As shown in FIG. 11, iWAVE may be used to infer the back EMF induced in the coils of a permanent magnet motor. In a similar manner, FIG. 18 shows how the complex input icWAVE algorithm can be used for motor control where a Park transform on signals from the readout of two of the three motor drive currents yields two signals that are then passed through the icWAVE algorithm operating at the drive frequency required of the motor.

In FIG. 18, a number of the components correspond to those shown in and described in relation to FIG. 11. Consequently, a description of the function of the components which are also found in FIG. 11 is not given here. The differences between the iWAVE based controller shown in FIG. 11 and the icWAVE based controller of FIG. 18 are in the processing stages immediately following the current sensors. Firstly, since icWAVE requires two inputs, two current sensors 1802 and 1804 are present in FIG. 18, where the outputs from the two currents sensors are passed through a Clarke transform 1806 before input into the icWAVE algorithm 1808 in order to transform the sensed currents to have a 90° phase difference and therefore fulfil the orthogonality requirements of the icWAVE. The outputs of the icWAVE are then mixed via mixers/multipliers 1810 and 1812 before the different between in the mixed signals is taken by subtractor 1814. More precisely, the D input to the icWAVE is mixed with the Q output of the icWAVE, and the Q input to the icWAVE is mixed with the D output of the icWAVE. The output of the subtractor is then processed in the same manner as described with reference to FIG. 11

The advantages of the icWAVE scheme over the iWAVE one are twofold; first, the combination of icWAVE outputs used, as for the RF communications application, removes the 2f component that frequently pollutes heterodyning phase sensors. Second, the icWAVE algorithm is simpler than iWAVE, with a reduced computational burden, and therefore simplified electronics may be used for motor control. In a similar manner to the demodulation scheme set out above, by varying the icWAVE w parameter, the icWAVE bandwidth may be set either to remove more noise or to allow a faster response to changes in the motor state, where adaptive algorithms may also adjust this bandwidth in response to the motor state. The real iWAVE algorithm described earlier has the advantage of only requiring a single current readout, whereas the icWAVE requires two inputs. However, a dual configuration may also be realised, where the default control used the icWAVE algorithm, but a single-sensor iWAVE algorithm could be substituted should one of the current sensors fail. Although the icWAVE implementation has been described above with reference to permanent magnet electric motors, it may be applied to any form of motor where two substantially orthogonal signals represent either current or voltage in the lines supplying power to the motor.

icWAVE Active Cavity Resonators

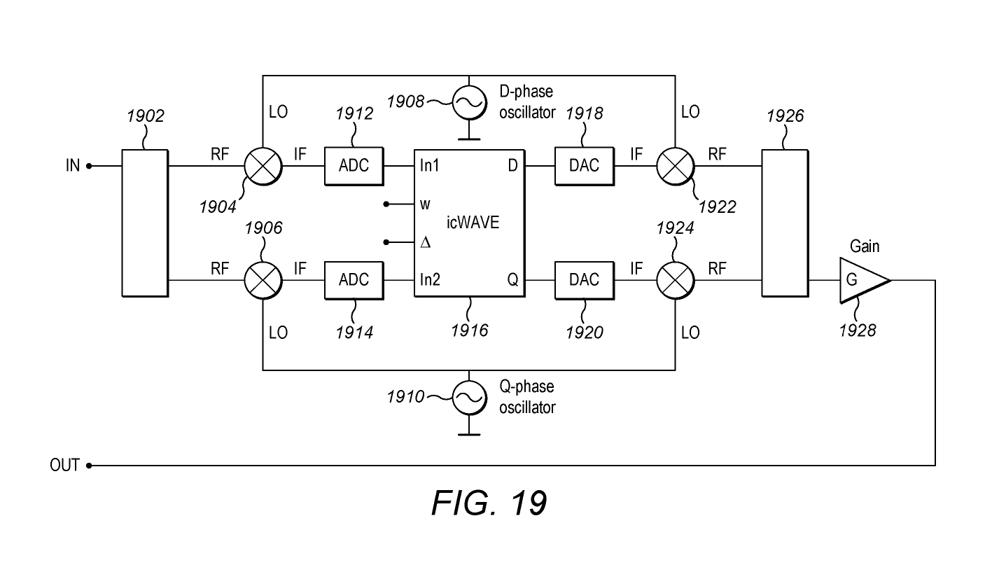

Narrowband microwave resonant circuits are useful in many electronic applications, but resonant structures at microwave frequencies are often difficult to fabricate and tune to different frequencies. The scheme shown in FIG. 19 shows how the complex icWAVE filter may be configured as part of a circuit implementing a narrowband resonant bandpass filter.

The circuit 1900 of FIG. 19 employs an initial splitter 1902 to form the two orthogonal inputs that are required for the icWAVE. The two orthogonal signals are then fed into a mixing stage for down converting to a lower IF. During the mixing stage, the D output from the splitter is mixed with a signal from a D-phase local oscillator 1908 by mixer 1904 and the Q phase output from the splitter is mixed with a signal from a Q-phase local oscillator 1910. However, a single local oscillator with appropriate phase shift may provide both local oscillator signals. The signals at the IF are then sampled by the analogue to digital converters 1912 and 1914 and passed into an icWAVE filter 1916 whose frequency is set to the difference between the passband frequency required and the local oscillator frequency. The icWAVE D and Q outputs are then converted back into the analogue domain by digital to analogue converters 1918 and 1920; the analogue signals are mixed back up to the RF frequency using mixers 1922 and 1924 and the signals from the local oscillators 1908 and 1910. Lastly, the RF signals are combined with one another by combiner 1926; and then amplified by amplifier 1928, before being output as the filtered signal.

A resonant circuit of high Q (quality factor) may be obtained by running this circuit in a feedback mode, where an RF structure operated either on resonance or below the cutoff for resonances of the structure may be included in the feedback circuit. An example of an RF structure operated below cutoff would be a parallel plate capacitor with plate separation significantly less than half the wavelength of the lowest mode of the RF structure, with one plate of the capacitor connected to the input of the resonant circuit using a suitable transmission line matching circuit, and the other plate connected to the output. Oscillating electric fields between the plates would then occur preferentially at the resonant frequency of the icWAVE filter plus the local oscillator frequency. By this method, RF circuits may be endowed with resonant properties that can be adjusted dynamically by altering the coefficients w and A of icWAVE. The local oscillator frequency may also be altered where large changes in the frequency of the resonant filter are required. More than one of these resonant filter structures may be operated in parallel. In this case, the RF structure will have several resonances, whose frequencies and Q-factors may be varied independently.

### REFERENCES

[1] J. H. Halberstein, Recursive, Complex Fourier Analysis for Real-Time Applications, Proc. IEEE 54 903, 1966.
[2] J. Smith, Modern Communications Circuits, First Edition, Wiley, 1968, Chapter 7.
[3] Herbert Goldstein, Classical Mechanics, Second Edition, Addison Wesley, 1980, 978-0201029185, Sections 10-5.
[4] Oppenheim and Schafer, Digital Signal Processing, First Edition, Prentice Hall, 1975, 978-0132146357, Chapter 2.

Further details of the present invention are set out in the following annex entitled “Complex-Tap IIR Filters for the Dynamic Characterisation of Sinusoids”

1. A method for recursively estimating at least one parameter of a first oscillating component represented by one or more sampled noisy input signal waveforms, the method comprising:
recursively generating from the one or more sampled noisy input signals an estimate of a Z-transform component corresponding to the first oscillating component;
forming, from the estimated Z-transform component, one or more signals providing an indication of one or more of a frequency and an amplitude of the Z-transform component; and
estimating, from the one or more signals, one or more of a frequency, a relative phase and an amplitude parameter of the first oscillating component.

2. The method as claimed in claim 1, wherein the generation of the Z-transform estimate is based on a complex generalised angular frequency corresponding to a predetermined oscillation frequency.

3. The method as claimed in claim 1, wherein the one or more signals includes a first wave and a second wave, the first wave being substantially in-phase with the first oscillating component and the second wave being substantially out-of-phase with the first oscillating component.

4. The method as claimed in claim 1, wherein the first oscillating component is represented by a first sampled noisy input signal waveform and the Z-transform component has a substantially elliptical locus in the complex plane, and wherein forming the one or more signals from the Z-transform includes transforming the Z-transform component, the transforming comprises one or more of:
aligning the major and minor axes of the elliptical locus with the real and imaginary axes;
mapping the aligned elliptical locus to a substantially circular locus; and
rotating the substantially circular locus so as to have an argument substantially equal to the phase of the first oscillating component.

5. The method as claimed in claim 4, wherein the square of the radius of the rotated substantially circular locus corresponds to an action variable of the first oscillating component and the argument of the rotated substantially circular locus corresponds to an angle variable of the first oscillating component, the action variable being given by the modulus of the transformed Z-transform component and the angle variable being given by the argument of the transformed Z-transform component.

6. The method as claimed in claim 3, wherein the first and second waves each have an amplitude substantially equal to the amplitude of the first oscillating component.

7. The method as claimed in claim 2, wherein the complex angular frequency includes a variable corresponding to a predetermined bandwidth associated with the Z-transform.

8. The method as claimed in claim 7, wherein the bandwidth of the Z-transform is less than a frequency at which the one or more input signal waveforms is sampled.

9. The method as claimed in claim 7, wherein the predetermined oscillation frequency and the predetermined bandwidth vary with time.

10. The method as claimed in claim 4, wherein the action variable corresponds to an estimate of the square of the amplitude of the first oscillating component, and the angle variable corresponds to the phase of the first oscillating component.

11. The method as claimed in claim 7, wherein the method further comprises tracking a frequency of the first oscillating component, the tracking comprising
estimating a frequency difference between the estimated frequency and the frequency of the first oscillating component; and
updating the predetermined oscillation frequency based upon the estimated frequency difference.

12. The method as claimed in claim 7, wherein the method further comprises estimating a frequency shift of the first oscillating component, the estimating comprising
estimating a frequency difference between the estimated frequency and the frequency of the first oscillating component;
updating the predetermined oscillation frequency based upon the estimated frequency difference; and
calculating a difference between frequency estimates of the first oscillating component before and after the updating of the predetermined oscillation frequency.

13. The method as claimed in claim 11, wherein estimating the frequency difference is performed using homodyne detection.

14. The method as claimed in claim 3, wherein the one or more sampled input signal waveforms include a second oscillating component, and the method includes
subtracting the first wave from the sampled input signal to generate a modified sampled input signal from which the first oscillating component has been substantially removed.

15. The method as claimed in claim 14, wherein the method comprises estimating one or more of a frequency, a relative phase and an amplitude parameter of the second oscillating component subsequent to subtracting the first wave from the one or more sampled input signal waveforms, using a method comprising:
recursively generating from the modified sampled input signal an estimate of a Z-transform component corresponding to the second oscillating component;
forming, from the Z-transform component corresponding to the second oscillating component, one or more further signals providing an indication of one or more of a frequency and an amplitude of the Z-transform component corresponding to the second oscillating component; and
estimating, from the one or more further signals, one or more of a frequency, a relative phase and an amplitude parameter of the second oscillating component.

16. The method as claimed in claim 15, wherein the one or more input signal waveforms correspond to a current flowing in a drive coil of an electric motor, and the first oscillating component corresponds to a drive current of the electric motor.

17. The method as claimed in claim 16, wherein the second oscillating component corresponds to a current induced by a back electromotive force associated with a rotation of a rotor of the electric motor relative to the stator of the electric motor, and a phase of the second oscillating component corresponds to a position of the rotor of the electric motor relative to a stator of the electric motor.

18. The method as claimed in claim 17, wherein the method comprises controlling, based on at least one of the estimated frequency, phase and amplitude of the second oscillating component, a drive voltage applied to the drive coil, and wherein the drive voltage comprises a sinusoid and controlling the drive voltage comprises
controlling one or more of the phase and amplitude of the sinusoid.

19. (canceled)

20. The method as claimed in claim 18, wherein the controlling of the drive voltage comprises
estimating a phase difference between the second oscillating component and the estimated phase of the second oscillating component;
decreasing the drive voltage amplitude when the phase of the second oscillating component leads the estimated phase of the second oscillating component; and
increasing the amplitude of the drive voltage if the phase of second oscillating component lags the estimated phase of the second oscillating component.

21-33. (canceled)

34. A parameter estimation apparatus configured to recursively estimating at least one parameter of a first oscillating component represented by one or more sampled noisy input signal waveforms, the apparatus comprising:
a Z-transform unit configured to generate from the one or more sampled input signals an estimate of a Z-transform component corresponding to the first oscillating component;
a forming unit configured to form, from the estimated Z-transform component, one or more signals providing an indication of one or more of a frequency and an amplitude of the Z-transform component; and
an estimating unit configured to estimate, from the one or more signals, one or more of a frequency, a relative phase and an amplitude parameter of the first oscillating component.

35-58. (canceled)
